(19) United States
(12) Patent Application Publication
(10) Pub. No.: US 2004/0157457 A1
(43) Pub. Date: Aug. 12, 2004

(54) Methods of using polymer films to form micro-structures

(76) Inventors: Songlin Xu, Fremont, GA (US); Thorsten Lill, Santa Clara, CA (US); Wan Cheng Goh, San Jose, CA (US)

Correspondence Address: PATENT COUNSEL, APPLIED MATERIALS, INC., Legal Affairs Department, P.O. BOX 450A, Santa Clara, CA, 95052, US

(21) Appl. No.: 10/366,598

(22) Filed: Feb. 12, 2003

(51) Int. Cl. H01L 21/311

(52) U.S. Cl. 438/694

(57) ABSTRACT

The present invention includes a method of using plasma polymers to form microstructures on substrates. The method includes the steps of forming a polymer film on a substrate having one or more layers of materials thereon in a plasma of a first process gas; removing a first part of polymer film in a plasma of a second process gas; etching the one or more layers of materials in a plasma of a third process gas; and removing a second part of the polymer film in a plasma of a fourth process gas. During the etching of the one or more layers of materials, the second part of the polymer film protects selected portions of the one or more layers of materials from being removed by the plasma of the third process gas.

The present application relates to semiconductor processing technology and particularly to forming micro-structures on substrates using plasma processes.

### BACKGROUND

Plasma techniques, such as plasma etching and deposition, have been widely used to form microstructures on semiconductor substrates. A microstructure typically includes one or more features, such as a line of material on a substrate, or a trench or hole in a layer of material on the substrate. These features may be part of an optical component or a device in an integrated circuit (IC). When performing a plasma etching or deposition process, a substrate is exposed to a plasma of a process gas. The plasma is typically generated by coupling power into a plasma chamber to energize the process gas therein. A portion of the process gas is thus turned into ions and neutral radicals. In the case of plasma deposition, the ions and neutral radicals react with each other to form a layer of film on the substrate. In the case of plasma etching, the ions and neutral radicals react with the substrate to selectively remove one or more materials on the substrate. Various process parameters such as the composition of the process gas, the amount of power coupled into the vacuum chamber, the pressure of the process gas in the plasma chamber, etc., are controlled to accomplish specific tasks.

A plasma process is complicated by many factors, including the uniformity of an etch or deposition rate across the substrate, differences in the etch or deposition rate between dense and isolated features (also known as microloading), and selectivity in the etch rate of one material with respect to the etch rates of other materials also exposed to the plasma. Other factors include the conformality of a plasma deposited film with underlying patterns previously formed on the substrate and the degree of anisotropy associated with a plasma etching process. As the speed and complexity of modern ICs continue to grow, the feature sizes of the microstructures in these ICs continue to shrink, resulting in greater and greater challenges when plasma processes are used to form these microstructures. To meet these challenges, plasma chambers are becoming more and more complicated, and in order to use one of these chambers to perform a plasma etching process, an extensive amount of engineering work is usually required to find the proper settings for the process parameters so that the plasma process produces high etch rate uniformity, low etch rate microloading, high etch rate selectivity, and in many cases, a very high degree of anisotropy. Sometimes, even after exploring all possible settings of the process parameters, the results are still not satisfactory.

### SUMMARY

The present invention includes a method of using plasma polymers as either sacrificial layers or mask materials when plasma processes are used to form microstructures on substrates. The method includes the steps of forming a polymer film on a substrate in a plasma of a first process gas; removing a first part of the polymer film from the substrate or from a layer of material previously formed on the substrate in a plasma of a second process gas; and etching the substrate or the layer of material on the substrate in a plasma of a third process gas. During the etching of the substrate or the layer of material, the second part of the polymer film protects selected portions of the substrate or selected portions of the layer of material or selected portions of another layer material on the substrate from being exposed to the plasma of the third process gas. In some applications, the protection provided by the second part of the polymer film allows the microstructures to be formed controllably and without extensive engineering work to optimize the plasma of the third process gas. In other applications, the second part of the polymer film acts as a mask with feature sizes beyond those that can be accomplished using conventional lithographic techniques.

In an illustrative embodiment of the present invention, the microstructures include lightly-doped drain (LDD) spacers in metal-oxide-semiconductor field effect transistors (MOSFET), and the polymer film is formed over a layer of spacer material covering a plurality of polysilicon gates formed on a semiconductor substrate. During the removal of the first part of the polymer film, all except a part of the polymer film covering the spacer material on sidewalls of the polysilicon gates is removed. The part of the polymer film on the sidewalls of the polysilicon gates protects the spacer material thereon during a subsequent spacer etching process. This way, LDD spacers such as ultra thin spacers, hanging spacers, recessed spacers, or footed spacers can be formed in a controllable manner.

In another embodiment of the present invention, the microstructures include notched gates in MOSFETs, and the polymer film is formed over a partially etched layer of gate material, such as polysilicon. During the removal of the first part of the polymer film, a part of the polymer film covering the sidewalls of the partially etched polysilicon gates is left in place. This part of the polymer film protects the sidewalls of the partially etched polysilicon gates during a subsequent etching process that etches the rest of the polysilicon gates in an isotropic fashion. As a result, notches are formed in the polysilicon gates in which a lower part of the gate undercuts an upper part of the gate.

In yet another embodiment of the present invention, the microstructures include silicon pillars for stacked memory cells. The silicon pillars are formed by etching into a silicon substrate or a layer of silicon on a substrate. To make the etching proceed vertically, polymer films are used to protect sidewalls of partially etched pillars, and the method of the present invention is repeatedly performed until a desired pillar height is reached.

In yet another embodiment of the present invention, the microstructures include polysilicon floating gates with electron injection tips covered by a thin layer of oxide for flash memory cells. The polymer films are used to protect the thin layer of oxide when the polysilicon floating gates are etched.

In yet another embodiment of the present invention, the microstructures are lines of a material, which lines are so narrow that they cannot be formed using conventional lithographic techniques. The polymer film is used as a mask when a layer of the material is etched in the third plasma.

The method further includes removing a second part of the polymer film in a plasma of a fourth process gas after the desired structures are formed.

In one embodiment of the present invention, the plasma of the first process gas, the plasma of the second process gas, the plasma of the third process gas and the plasma of the forth process gas are generated consecutively in a single plasma etcher, so that the method of the present invention can be performed without transferring the substrates from one plasma chamber to another. By eliminating the substrate transfers, the time required to carry out the method of the present invention and the likelihood of defect formation can be greatly reduced. In one embodiment of the present invention, the polymer film is a polymer film formed by exposing the substrate to a plasma of a process gas in the plasma etcher. The process gas includes gaseous components commonly used for plasma etching so that there is no need of hardware modifications in order to form the polymer films in the plasma etcher. In one embodiment, the gaseous components include a fluorocarbon or hydrofluorocarbon gas and a hydrogen-containing inorganic gas such as HBr or HCl.

### DRAWINGS

Additional objects and features of the invention will be more readily apparent from the following detailed description and appended claims when taken in conjunction with the drawings, in which:

FIG. 1 is a flowchart illustrating a method of using polymer films as a sacrificial layer to form a structure on a substrate according to one embodiment of the present invention;

FIG. 2A is a schematic view in vertical cross-section of an illustrative plasma etcher that can be used to perform one or more steps in the method according to one embodiment of the present invention;

FIG. 2B is a flowchart illustrating a process for forming a polymer film according to one embodiment of the present invention;

FIGS. 3A-3D are charts illustrating the effect of process parameter variations on the thickness of the polymer films formed according to one embodiment of the present invention.

FIGS. 4A-4D are FTIR spectra of the polymer films formed on blank silicon substrates using different process parameters according to one embodiment of the present invention;

FIG. 5A is a block diagram illustrating a polymer film formed on a patterned substrate according to one embodiment of the present invention;

FIG. 5B is a chart illustrating the thickness of the polymer film deposited on a patterned substrate as a function of deposition time according to one embodiment of the present invention;

FIGS. 6A-6C are charts illustrating the effect of process gas composition on the thickness, conformality, and microloading, respectively, of polymer films formed on patterned substrates according to one embodiment of the present invention;

FIGS. 7A-7C are charts illustrating the effect of process gas pressure on the thickness, conformality, and microloading, respectively, of the polymer films formed on patterned substrates according to one embodiment of the present invention;

FIG. 8A-8C are charts illustrating the effect of process gas flow rate on the thickness, conformality, and microloading, respectively, of the polymer films formed on patterned substrates according to one embodiment of the present invention;

FIG. 9A-9C is chart illustrating the effect of the source power on the thickness, conformality, and microloading, respectively, of the polymer films formed on patterned substrates according to one embodiment of the present invention;

FIG. 10A-10C are charts illustrating the effect of the bias power on the thickness, conformality, and microloading, respectively, of the polymer films formed on patterned substrates according to one embodiment of the present invention;

FIGS. 11A to 11D are charts illustrating the effect of process parameter variations on the resistance of the polymer films formed therewith to silicon or polysilicon etching processes, according to one embodiment of the present invention;

FIGS. 12A to 12F are block diagrams illustrating a process of forming ultra-thin spacers using a polymer film as a sacrificial layer according to one embodiment of the present invention;

FIGS. 12G to 12I are block diagrams illustrating a process of forming recessed spacers using a polymer film as a sacrificial layer according to one embodiment of the present invention;

FIGS. 12J to 12L are block diagrams illustrating a process of forming footed spacers using a polymer film as a sacrificial layer according to one embodiment of the present invention;

FIGS. 12M to 12O are block diagrams illustrating a process of forming hanging spacers using a polymer film as a sacrificial layer according to one embodiment of the present invention;

FIGS. 13A and 13B are block diagrams illustrating a prior art process of forming spacers;

FIGS. 14A to 14F are block diagrams illustrating a process of forming notched gates using a polymer film as a sacrificial layer according to one embodiment of the present invention;

FIGS. 15A to 15H are block diagrams illustrating a process of forming silicon pillars using polymer films as sacrificial layers according to one embodiment of the present invention;

FIGS. 16A to 16F are block diagrams illustrating a process of forming polysilicon floating gates with thin oxide covered injection tips according to one embodiment of the present invention;

FIGS. 17A to 17F are block diagrams illustrating a process of forming thin lines using polymer film masks according to one embodiment of the present invention.

### DESCRIPTION

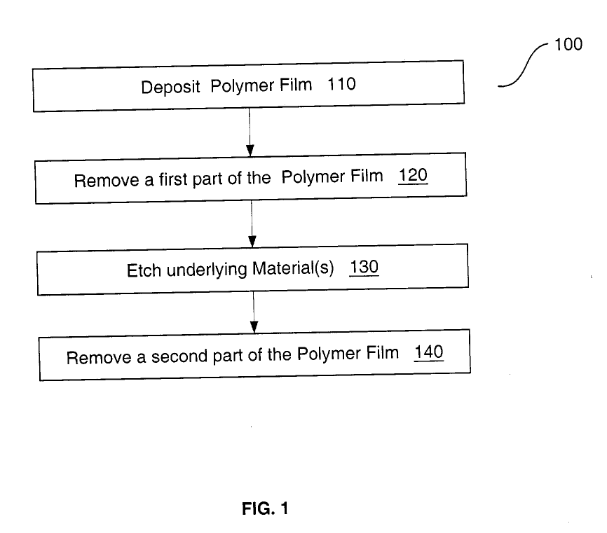

The present invention includes a method of using polymer films to form microstructures on substrates. As shown in FIG. 1, the method 100 in one embodiment of the present invention includes step 110 in which a polymer film is formed on a substrate by exposing the substrate to a plasma of a first process gas. The substrate may have one or more layers of materials previously formed thereon and the polymer film covers the one or more layers of materials. Method 100 further includes step 120 in which a first part of the polymer film is removed from portions of the substrate and/or from portions of one or more layers of materials previously formed on the substrate by exposing the substrate to a plasma of a second process gas. Method 100 further includes step 130, in which at least one of the one or more layers of materials is etched in a plasma of a third process gas. After the microstructures are formed, step 140, in which a second part of the polymer film is removed in a plasma of a fourth process gas, is performed by method 100.

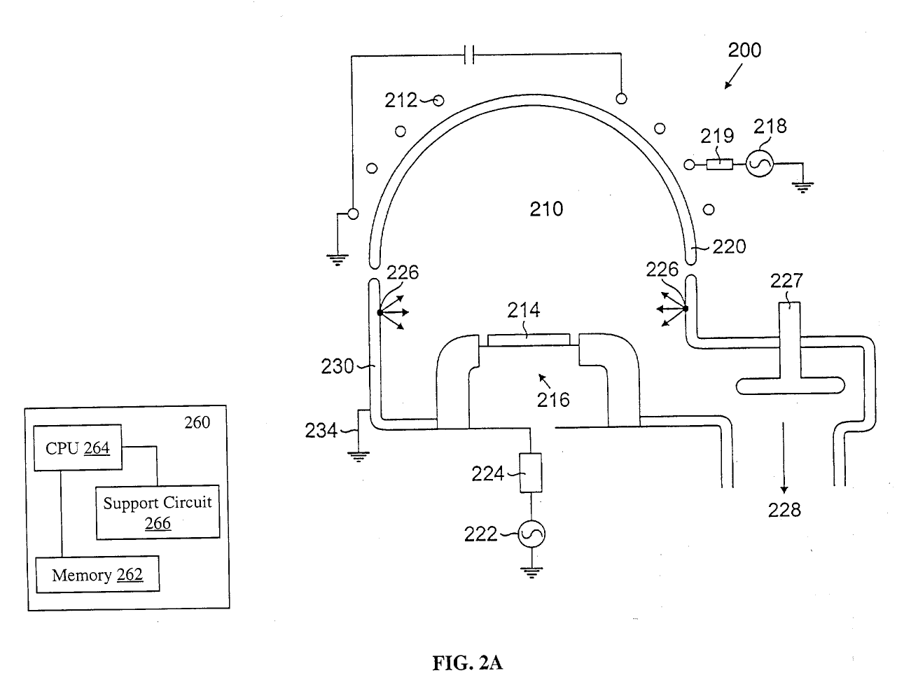

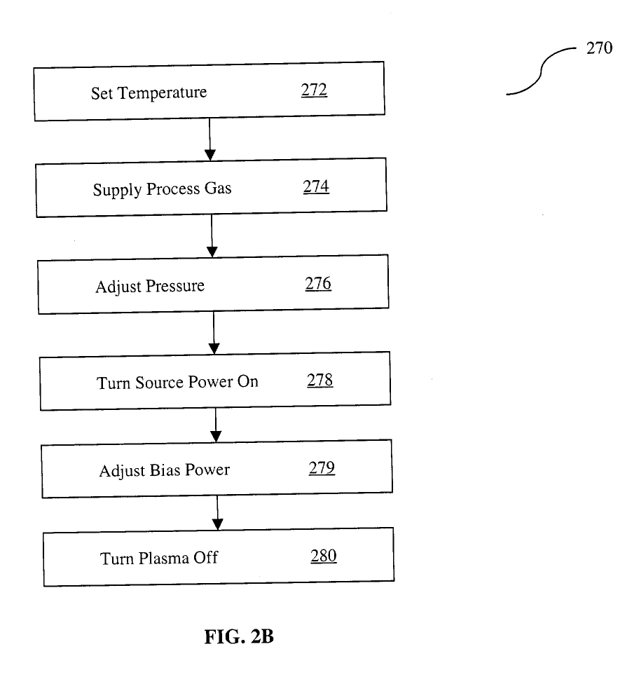

In step 110, a conventional polymer-forming plasma can be used to form the polymer film, examples of which include the low-density plasma of hydrocarbon gases described by Wagner and Koidl in “Process Monitoring of α-C:H Plasma Deposition,” J. Vac. Sci. Technol. A 5(4), July/August 1987, which is incorporated herein by reference in its entirety, and the high-density plasma of hydrocarbon gases decribed by X. Chen, et al. in “Amorphous Hydrogenated Carbon film Formation from Benzene by Electron Cyclotron Resonance Chemical Vapor Deposition,” J. Vac. Sci., Technol. A 18(1), January/February 2000, which is also incorporated herein be reference in its entirety. Alternatively, the polymer-forming process described below in association with FIGS. 2A to 11D, inclusive, can also be used to form the layer of polymer film.

In step 120, to remove the first part of the polymer film, a conventional polymer etching process can be used, an example of which is a polymer etching process using an O₂/Cl₂ plasma in a plasma etcher. After removal of the first part of the polymer film, a remaining part of the polymer film is left to protect selected portions of the one or more layers of materials from being removed by the plasma of the third process gas in step 130. The plasma of the third process gas can be a plasma of a conventional etching process for etching the at least one of the one or more layers of materials. For example, when the material to be etched is polysilicon, the plasma of the third process gas can be a HBr/Cl₂ plasma formed in a plasma etcher configured for polysilicon etching. In step 140, a conventional polymer etching process using, for example, an O₂ and/or N₂ plasma in a plasma etcher or asher can be used to remove the second part of the polymer film.

Illustrative plasma etchers that can be used to perform steps 110, 120, 130, and/or 140 include a decoupled plasma source (DPS) reactor, available from Applied Materials, Inc., in Santa Clara, Calif., a schematic diagram of which is shown in FIG. 2A. The DPS reactor is also disclosed in U.S. Pat. No. 6,074,954, the entire disclosure of which is incorporated by reference herein.

Referring to FIG. 2A, the DPS reactor (reactor) 200 includes a process chamber (chamber) 210 having a dielectric, dome-shaped ceiling 220, and two radio frequency (RF) power generators. Exterior to the ceiling 220 is an inductive coil antenna segment 212 that is connected to a first RF power generator 218 through an impedance matching network 219. The first RF power generator may be a source power generator with a frequency tunable around 12.56 MHz for impedance matching at different plasma conditions, or it may be a source power generator of fixed frequency which is connected to the coil antenna segment 212 through an impedance matching network 219. Interior to the chamber 210 is a pedestal 216 for supporting a substrate 214. The pedestal 216 is connected to a second RF power generator 222 through an impedance matching network 224. The second RF power generator may be a bias power generator operating at a fixed frequency in the range between about 400 kHz and 13.56 MHz). The chamber 210 further includes a conductive chamber wall 230 that serves as an electrical ground of the reactor 200. The chamber wall 230 is electrically isolated from the pedestal 216.

To strike a plasma in the chamber 210, gaseous components are introduced into the chamber 210 by a gas supply system (not shown) through gas entry ports 226 to form a process gas, and either or both of the two power generators can be turned on to energize the process gas. The pressure of the process gas in the process chamber 210 is controlled by a vacuum pump (not shown) and a throttle valve 227 in an exhaust port 228.

Since both the chamber wall 230 and the substrate 214 can be heated by the plasma, the reactor 200 further includes cooling mechanisms for controlling the temperature of the chamber wall 230 and the substrate 214. The temperature of the chamber wall 230 is controlled using liquid-containing conduits (not shown) which are located in the chamber wall 230. The temperature of the substrate 214 is controlled by stabilizing the temperature of the support pedestal 216 and flowing a helium gas in channels formed by the back side of the substrate 214 and grooves (not shown) on the pedestal surface. The helium gas facilitates heat transfer between the pedestal and the substrate 214.

A controller 260 comprising a central processing unit (CPU) 264, a memory 262, and support circuits 266 for the CPU 264 is coupled to the various components of the reactor 200 such as the power supplies 218, 222, the gas supply system and throttle valve 227 to facilitate control of the process parameters during the formation of the polymer film. The memory 262 can be any computer-readable medium, such as random access memory (RAM), read only memory (ROM), floppy disk, hard disk, or any other form of digital storage, local or remote to the reactor 200 or CPU 264. The support circuits 266 are coupled to the CPU 264 for supporting the CPU in a conventional manner. These circuits include a cache, power supplies, clock circuits, input/output circuitry and subsystems, and the like.

FIG. 2A only shows one configuration of various types of plasma etchers that can be used to perform one or more steps in the method 100. Besides the DPS reactor, other examples of plasma reactors for carrying out the steps in the method of the present invention include different configurations of inductively coupled plasma (ICP) reactors, electron-cyclotron reactors (ECR), triode reactors, and the like.

Method 100 can be used to form various microstructures that require highly selective removal of portions of one of more layers of materials. Or, it can be used to form microstructures with feature sizes so small that they cannot be formed using conventional photolithography technologies. An illustrative application of method 100 is to form ultra-thin lightly-doped drain (LDD) spacers in modern metal-oxide-silicon field effect transistors (MOSFET). FIGS. 13A-13B illustrate a conventional process for forming spacers in MOSFETs. As shown in FIG. 13A, a layer of dielectric material 1310, such as silicon dioxide or silicon nitride, is deposited using a conventional low-pressure chemical vapor deposition (LPCVD) process to cover one or more polysilicon gates 1320 formed on a gate oxide layer 1330, which is in turn formed on a silicon substrate 1340. The layer of dielectric material is then etched in a conventional dielectric etching process to selectively remove the dielectric material on horizontal surfaces, leaving the dielectric material on vertical surfaces, such as sidewalls 1322 of the gate 1320, as spacers, as shown in FIG. 13B. To form the spacers, it is desired that the dielectric etching process anisotropically strips off the dielectric material in a vertical direction so that the thickness A of the dielectric material as deposited on vertical surfaces 1322 is not significantly reduced during the dielectric etching process.

Conventional dielectric etching processes, however, are usually not completely anisotropic. Thus, even with careful selection of the process parameters, lateral etching as well as vertical etching is observed in these etching processes. This means that while the dielectric material on horizontal surfaces is being etched away, the dielectric material on the sidewalls 1322 of the gate also becomes thinner. The amount of lateral etching is tolerable when the thickness δ of the spacers to be formed is relatively thick, as shown in FIG. 2B. But when δ is very thin, the existence of lateral etching can make it difficult to control the spacer etching process such that a desired spacer thickness is reached.

Several factors associated with the dielectric etching process contribute to this difficulty. First, the selectivity of the dielectric etching process with respect to the gate oxide 1330 is usually limited. So, when portions of the dielectric layer 1310 on the gate oxide layer 1330 are removed, further etching to thin down the dielectric layer on gate sidewalls 1322 may cause excessive etching through the gate oxide layer 1330 and into the silicon substrate 1340. Therefore, to form the very thin spacers, the dielectric layer 1310 as deposited needs to be thin. Second, there is usually a considerable amount of etch rate microloading in the dielectric etching process, and etch rate uniformity across the substrate is often not ideal. Therefore, in order to completely clear the dielectric material 1310 on horizontal surfaces, a significant amount of over etching is usually required, resulting in further loss of the thin dielectric material on sidewalls 1322. Sometimes, the dielectric material 1310 on the gate sidewalls 1322 can be attacked so severely that there is hardly any spacer left after the spacer etching process.

The above problems of the prior art process for forming MOSFET LDD spacers can be solved by using the method of the present invention, as illustrated in FIG. 1 and in FIGS. 12A to 12F. FIG. 12A shows a line of conductive material 1210 formed over a gate dielectric layer 1205 on a semiconductor substrate 1200. The line of conductive material, such as polysilicon, can be a MOSFET gate, and can be formed using a conventional process for forming MOSFET gates. As shown in FIG. 12B, one or more layers of spacer material 1215, such as silicon dioxide and/or silicon nitride, is then deposited over the substrate 1200 by subjecting the substrate 1200 to, for example, one or more conventional low-pressure chemical vapor deposition (LPCVD) processes. An LPCVD process can usually be controlled so that a desired thickness τ of the spacer material(s) is formed over a sidewall 1214 of the gate 1210.

As shown in FIG. 1 and FIG. 12C, when method 100 is used to form the spacers, in step 110 in method 100, a polymer film 1220 is formed over the spacer material(s) 1215. Thereafter, in step 120 of the method 100, a first part of the polymer film is removed. As shown in FIG. 12D, the first part of the polymer film includes a part of the polymer film on horizontal surfaces, i.e., the part of the polymer film not covering the sidewalls 1214 of the gate 1210. In one embodiment of the present invention, an anisotropic or near anisotropic polymer etching process is used to remove the first part of the polymer film 1220. As an example, the polymer film 1220 can be etched in the DPS reactor 200 using O₂/Cl₂ as the process gas, 4 mT gas pressure, 500 W source power, 60 W bias power, and 30/70 standard cubic centimeter per minute (sccm) flow rates for the O₂/Cl₂ gaseous components in the process gas. This polymer etching process may have a isotropic component that removes some of the polymer film on the sidewalls 1214 of the gate, so that the polymer film thereon is thinner than when it was deposited.

The polymer film 1220 left on the sidewalls 1214 of the gate 1210 protects portions of the spacer material(s) 1215 between the polymer film and the gate during the subsequent step 130, in which the spacer material(s) is etched to remove a part of the spacer material(s) not covering the sidewalls 1214 of the gate, as shown in FIGS. 1 and 12E. After the spacer etching step 130, the polymer film 1220 is stripped in step 140, as shown in FIGS. 1 and 12F, by exposing the substrate to an O₂ plasma in a plasma etcher, such as the DPS reactor, leaving only the spacers 1230 on the sidewalls 1214 of the gate 1210.

In one embodiment of the present invention, the spacer material(s) includes SiN and a conventional SiN etching process can be used in step 130. An example of such a process is an etching process performed in the DPS etcher using SF_{6/}BBr/N₂ as the process gas where the gas pressure is about 70 mT, the source power is about 800 W, the bias power is 0, and the flow rates for the SF₆/HBr/N₂ gaseous components are about 50/100/50 sccm, respectively. This process has very high etch selectivity to gate oxide but it includes a significant isotropic etching component. Without the polymer film protection, this etching process usually removes the spacer material on the gate sidewall 1214 as well as on other parts of the substrate, making it hard to control the thickness of the spacer material left on the sidewall 1214 of the gate 1210, especially during the formation of ultra-thin spacers. With the polymer film protection, the spacer material on the sidewall 1214 is not affected significantly by the spacer etching process, so that the original thickness τ of the spacer material(s) can be retained. Thus the thickness of the spacers can be controlled by controlling the LPCVD process for depositing the spacer material(s).

As shown in FIGS. 12M to 12O, method 100 can also be used to form hanging spacers. To form the hanging spacers, after the first part of the polymer film is removed, as shown in FIG. 12M, an isotropic instead of anisotropic spacer etching process is used to etch the spacer material(s) 1215. In addition to removing the spacer material not covering the sidewall 1214 of the gate 1210, the isotropic spacer etching process also removes a top part and a bottom part of the spacer material(s) between the gate and the polymer film, leaving only a middle part of the spacer material(s) between the gate and the polymer film, as shown in FIG. 12N. The polymer film 1220 is then stripped in step 140 by exposing the substrate to an O₂ plasma in a plasma etcher, such as the DPS reactor, leaving only the hanging spacers 1230 on the middle part of the sidewalls 1214 of the gate 1210, as shown in FIGS. 120.

In one embodiment of the present invention, the spacer material(s) includes SiN and a conventional SiN etching process having a large isotropic etching component can be used in step 130. An example of such a process is an etching process performed in the DPS etcher using SF₆/HBr/N₂ as the process gas, where the gas pressure is about 70 mT, the source power is about 800 W, the bias power is 0, and the flow rates for the SF₆/HBr/N₂ gaseous components are about 50/100/50 seem, respectively.

As shown in FIGS. 12G to 12I, method 100 can also be used to form recessed spacers. To form the recessed spacers, after the polymer film 1220 is formed over the spacer material(s) 1215 in step 110, in step 120 of the method 100, a first part of the polymer film is removed. As shown in FIG. 12G, the first part of the polymer film includes the part of the polymer film not covering the sidewalls 1214 of the gate 1210 and the part of the polymer film covering upper portions 1216 of the sidewalls 1214. In one embodiment of the present invention, an anisotropic or near anisotropic polymer etching process is used to remove the first part of the polymer film 1220. As an example, the polymer film 1220 can be etched in the DPS reactor 200 using O₂/Cl₂ as the process gas, 4 mT gas pressure, 500 W source power, 60 W bias power, and 30/70 sccm flow rates for the O₂/Cl₂ gaseous components of the process gas, respectively.

A remaining part of the polymer film covers lower portions of the sidewalls 1214 of the gate 1210, and protects the spacer material(s) between the polymer film and the gate during the subsequent step 130, in which the spacer material(s) is etched to remove a part of the spacer material(s) not covering the sidewalls 1214 of the gate, and is further etched to remove a part of the spacer material(s) on the upper portions of the sidewalls 1214 of the gate, as shown in FIG. 12H. When the spacer material(s) includes SiN, a conventional SiN etching process can be used in step 130. An example of such a process is an etching process performed in the DPS etcher using SF₆/Br/N₂ as the process gas where the gas pressure is about 70 mT, the source power is about 800 W, the bias power is 0, and the flow rates for the SF₆/HBr/N₂ gaseous components are about 50/100/50 sccm, respectively. After the spacer etching step 130, the polymer film 1220 is stripped in step 140, as shown in FIG. 12I, by exposing the substrate to an O₂ plasma in a plasma etcher, such as the DPS reactor, leaving only the spacers 1230 on the sidewalls 1214 of the gate 1210.

As shown in FIGS. 12J to 12L, method 100 can also be used to form footed spacers. To form the footed spacers, a relatively thick polymer film 1230 is deposited in step 110 of the method 100. Thereafter, a first part of the polymer film is remove in step 120. As shown in FIG. 12J, the first part of the polymer film includes the part of the polymer film not covering the sidewalls 1214 of the gate 1210. In one embodiment of the present invention, an anisotropic or near anisotropic polymer etching process is used to remove the first part of the polymer film 1220. As an example, the polymer film 1220 can be etched in the DPS reactor 200 using O₂/Cl₂ as the process gas, 4 mT gas pressure, 500 W source power, 60 W bias power, and 30/70 sccm flow rates for the O₂/Cl₂ gaseous components in the process gas, respectively.

The remaining part of the polymer film is left on the sidewalls 1214 of the gate 1210 to protect the spacer material(s) between the polymer film and the gate 1210 and between the polymer film and the gate oxide 1205 during the subsequent step 130, in which the spacer material(s) is etched. Because the polymer film 1220 is relatively thick, part of the spacer material between the polymer film 1220 and the gate oxide layer 1205 is left in place after the spacer etching step 130, resulting in the footed spacers 1230, as shown in FIG. 12K. When the spacer material(s) includes SiN, a conventional SiN etching process can be used in step 130. An example of such a process is an etching process performed in the DPS etcher using SF₆/HBr/N₂ as the process gas where the gas pressure is about 70 mT, the source power is about 800 W, the bias power is 0, and the flow rates for the SF₆/HBr/N₂ gaseous components are about 50/100/50 sccm, respectively. After the spacer etching step 130, the polymer film 1220 is stripped in step 140, as shown in FIG. 12L, by exposing the substrate to an O₂ plasma in a plasma etcher, such as the DPS reactor, leaving only the footed spacers 1230 on the sidewalls 1214 of the gate 1210.

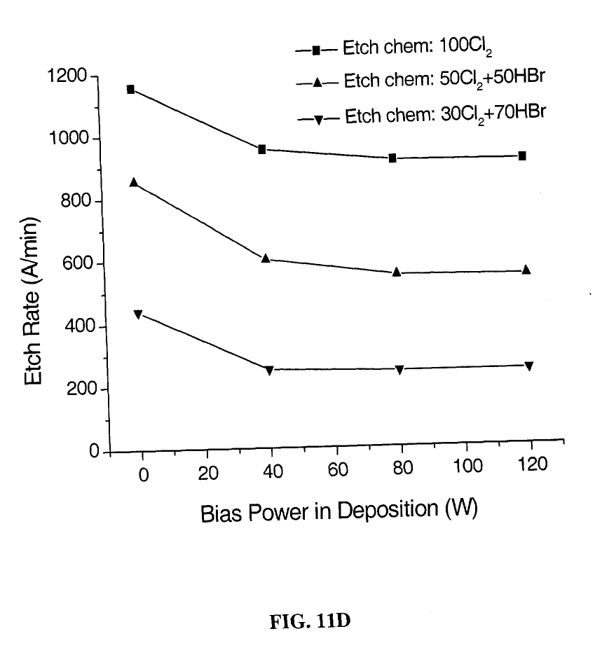

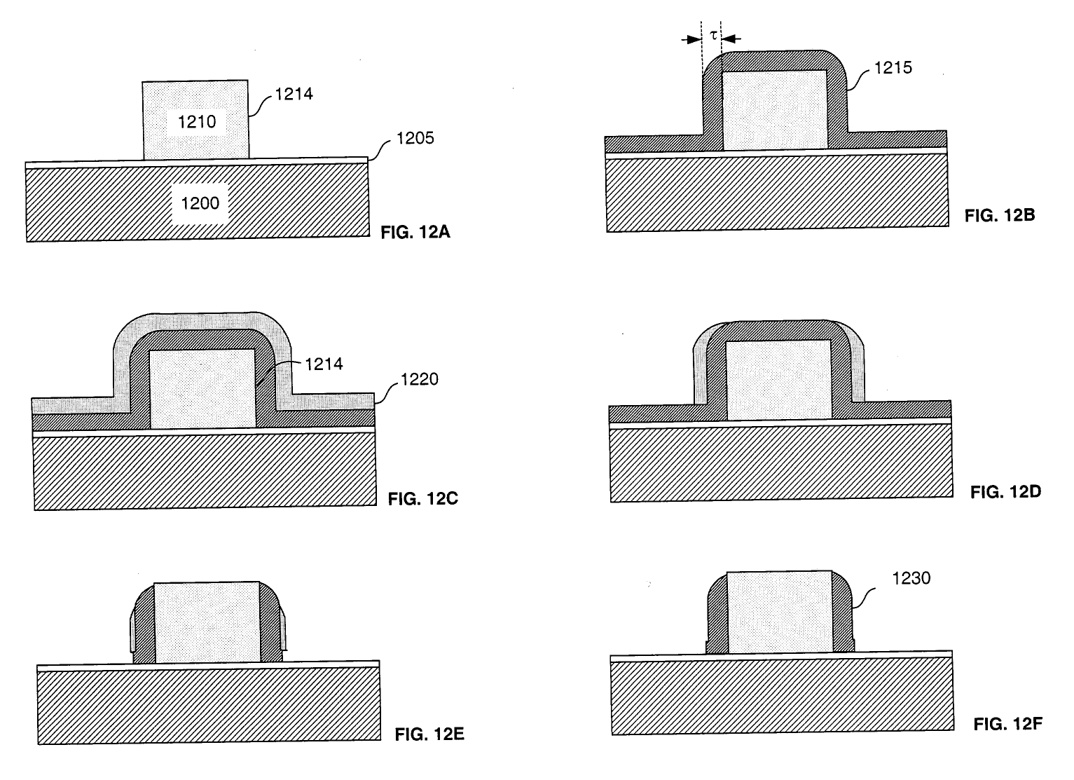

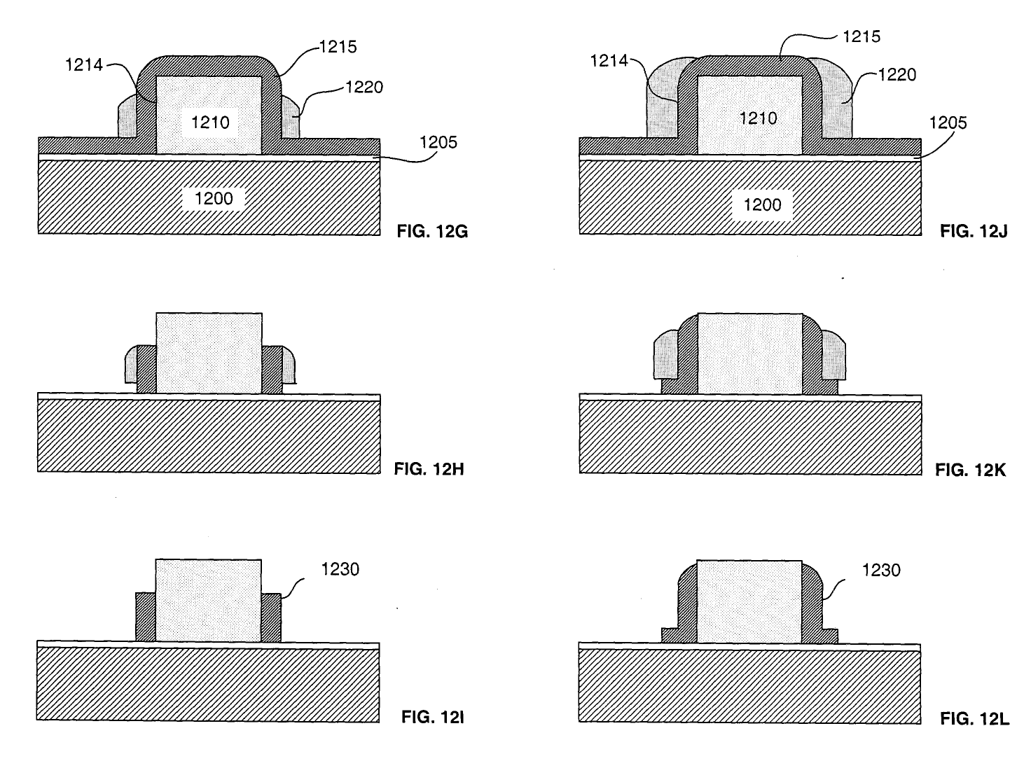

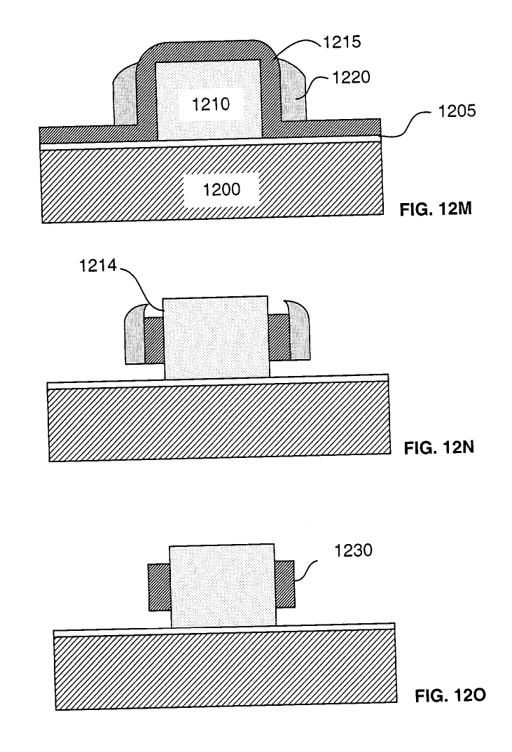

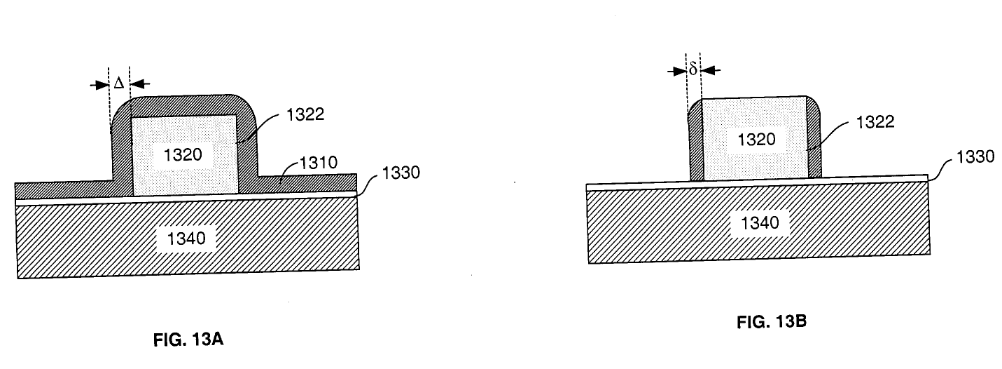

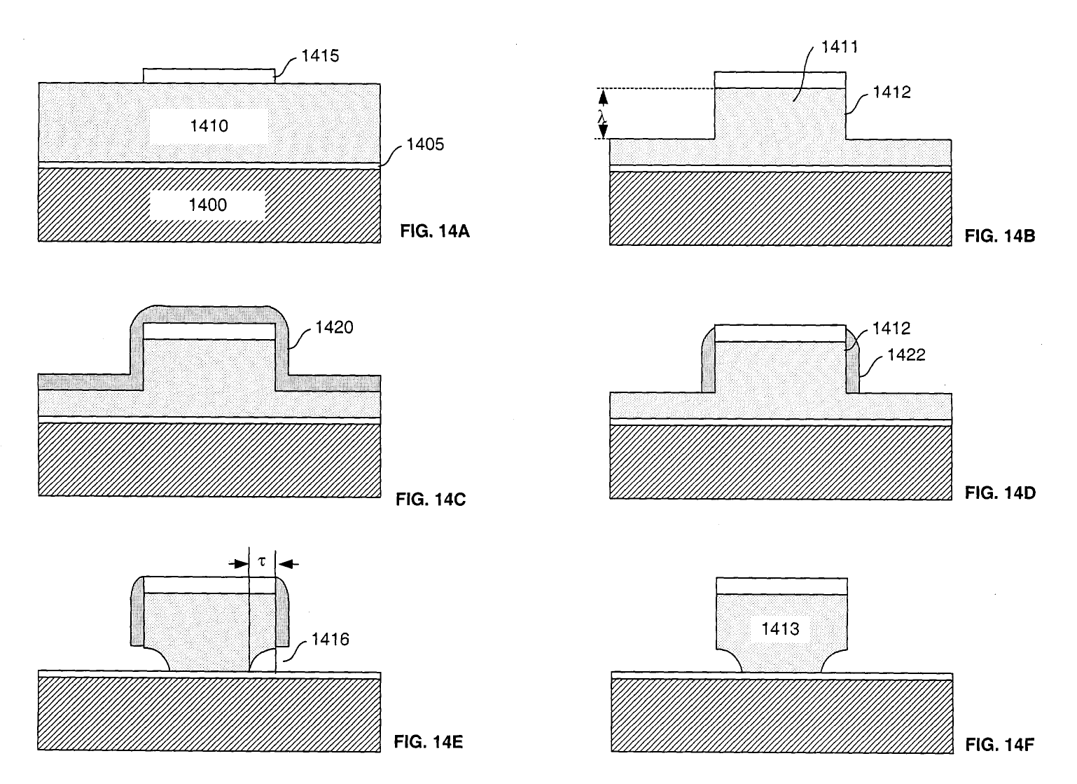

In another application, method 100 is used to form notched MOSFET gate(s), as shown in FIGS. 1 and 14A-14F. MOSFETS with notched gates have been shown to have improved current drive and suppressed short-channel effects compared to MOSFETS with conventional gate structures. FIG. 14A shows a layer of conductive material 1410, such as polysilicon over a dielectric layer 1405 covering a semiconductor substrate 1400. A conventional process can be used to deposit the conductive material. A hard mask 1415 over the layer of conductive material 1410 defines the gate to be etched. The hard mask can be a silicon dioxide mask formed using a conventional hard mask formation process. The layer of conductive material 1410 is then partially etched to form an upper part 1411 of a gate, as shown in FIG. 14B. A conventional gate etching process that anisotropically etches a part of the conductive material not covered by the hard mask 1415 can be used to form the upper part 1411 of the gate. In one embodiment of the present invention, the layer of conductive material 1410 is polysilicon and the partial etching of the layer of conductive material is performed in the DPS reactor using Cl₂/HBr as the process gas where the pressure is 50 mT, the source power is 800 W, the bias power is 20 W, and the Cl₂/HBr flow rates are 20/80 sccm, respectively. The partial etching of the layer of conductive material is performed until a predetermined height λ of the upper part 1411 of the gate is reached.

As shown in FIG. 1 and FIG. 14C, when method 100 is used to form notched gates, in step 110, a polymer film 1420 is formed to cover the partially etched layer of conductive material 1410 and the hard mask 1415. Afterwards, the polymer film is etched in step 120 to remove a first part of the polymer film. As shown in FIG. 14D, the first part of the polymer film includes the part of the polymer film not on sidewalls 1412 of the upper part 1411 of the gate. As an example, the polymer film can be etched in the DPS reactor using O₂/Cl₂ as the process gas where the gas pressure is about 4 mT, the source power is about 500 W, the bias power is about 60 W, and the flow rates for the O₂/Cl₂ gaseous components are about 30/70 sccm, respectively. A second part of the polymer film, which includes a part of the polymer film 1422 on sidewalls 1412 of the upper part 1411 of the gates is left to protect the upper part 1411 of the gate during the subsequent step 130, in which a lower part of the gate is etched.

During step 130, in which the lower part 1414 of the gate is etched, an isotropic or near isotropic etching process is used to etch the exposed part of the conductive material 1410 so that notches 1416 are formed under the upper part 1411 of the gate, as shown in FIG. 14E. In one embodiment of the present invention, the layer of conductive material 1410 is polysilicon and step 130 is performed in the DPS reactor using Cl₂/HBr as the process gas where the gas pressure is about 50 mT, the source power is about 800 W, the bias power is 20 W, and the flow rates for the Cl₂/HBr gaseous components are about 20/80 sccm, respectively. With the polymer film protection of the upper part of the gate(s), a depth τ of the notches can be precisely controlled by controlling the time of the etching process in step 130. After notches 1416 are formed, the polymer film 1420 is stripped in step 140 using an O₂ plasma, leaving the notched gate(s) 1413 on the substrate 1400.

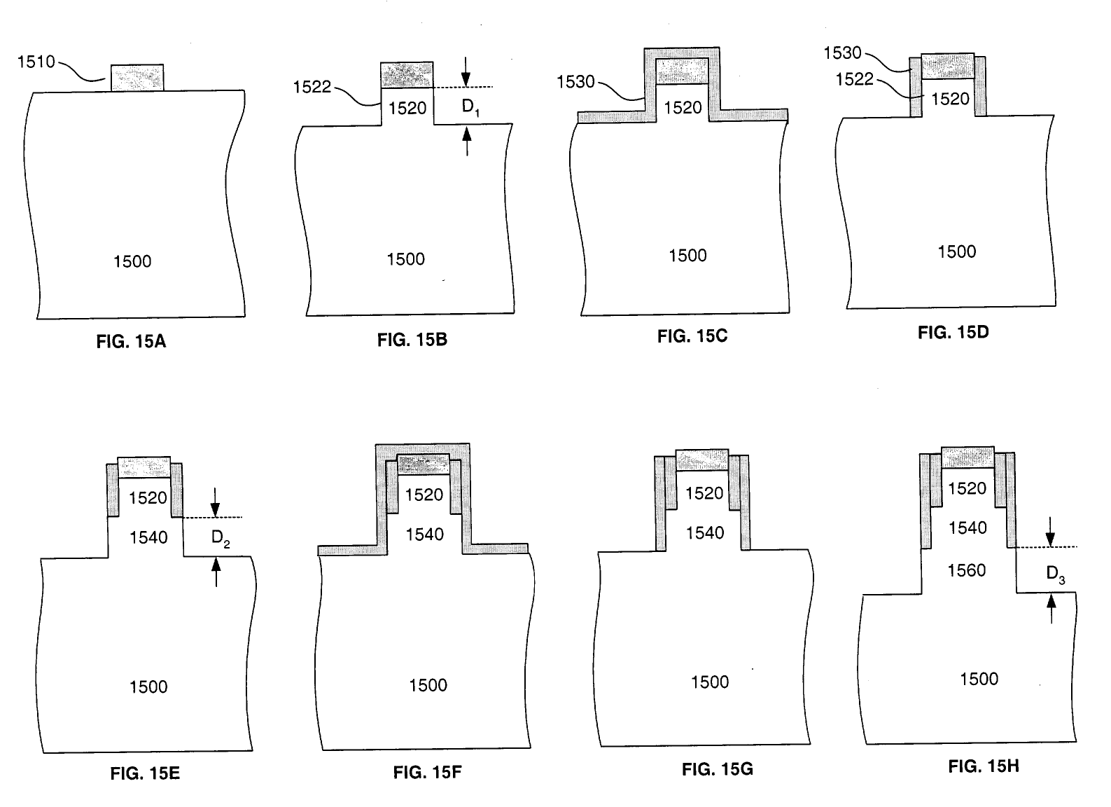

The method of the present invention can also be used to form silicon pillars for stacked memory devices, such as those describe by Endoh, et al., in “Novel Ultra High Density Flash Memory with a Stacked-Surrounding Gate Transistor (S-SGT) Structured Cell,” Technical Digest, IEDM 2001, p.2.3.1-4, which is incorporated herein by reference in its entirety. As shown in FIG. 15A, to form the silicon pillars, a hard mask such as silicon dioxide mask 1510 is first formed over a silicon substrate 1500 or a layer of a silicon material 1500 on another substrate (not shown) to define one or more pillars to be etched, and the silicon substrate or the layer of silicon material 1500 is anisotropically etched to a first step depth D₁ to form a first part 1520 of the pillars, as shown in FIG. 15B. Then in step 110 in method 100, a polymer film 1530 is formed over the silicon substrate or the layer of silicon material 1500, as shown in FIG. 15C. Thereafter, in step 120 of the method 100, a part of the polymer film 1530 on horizontal surfaces, i.e., the part of the polymer film not covering the sidewalls 1522 of the first part 1520 of the pillars, is removed. In one embodiment of the present invention, an anisotropic or near anisotropic polymer etching process is used to remove the part of the polymer film 1220. As an example, the polymer film 1220 can be etched in the DPS reactor 200 using O₂/Cl₂ as the process gas, 4 mT gas pressure, 500 W source power, 60 W bias power, and 30/70 sccm flow rates for the O₂/Cl₂ components of the process gas, respectively.

A remaining part of the polymer film is left on the sidewalls 1522 of the first part 1520 of the pillars to protect the sidewalls 1522 from being exposed to the plasma during the subsequent step 130, in which the silicon substrate or the layer of silicon material 1500 is further etched to a second step depth D₂ to form a second part 1540 of the pillars, as shown in FIG. 15E. Afterwards, steps 110 to 130 in method 100 are repeated and a third part 1560 of the pillars with a step height D₃ are formed, as shown in FIGS. 15F to 15H. Steps 110 and 130 can be repeated one or more times until a desired height of the pillars is reached. After the pillars are formed, the polymer films are stripped in step 140, by exposing the substrate to an O₂ plasma in a plasma etcher, such as the DPS reactor.

In one embodiment of the present invention, a conventional silicon etching process that anisotropically etches the silicon substrate or the layer of silicon material 1500 is used in step 130 when method 100 is used to form the silicon pillars. For example, step 130 may be performed in the DPS reactor using Cl₂/HBr as the process gas where the pressure is 4 mT, the source power is 500 W, the bias power is 80 W, and the Cl₂/HBr flow rates are 60/120 sccm, respectively. With the polymer film protection, the parts of the pillars already formed are not affected when the silicon substrate or the layer of silicon material 1500 is further etched to reach a desired pillar height. This way, by repeatedly performing steps 110 to 130 in method 100, the pillars can be formed successfully without excessive engineering work to eliminate or reduce the isotropic component in the silicon etching process. The thickness of the polymer films and/or the step heights D₁, D₂, D₃ . . . , of each part of the pillars can be adjusted to obtain a desired sidewall slope or profile for the pillars.

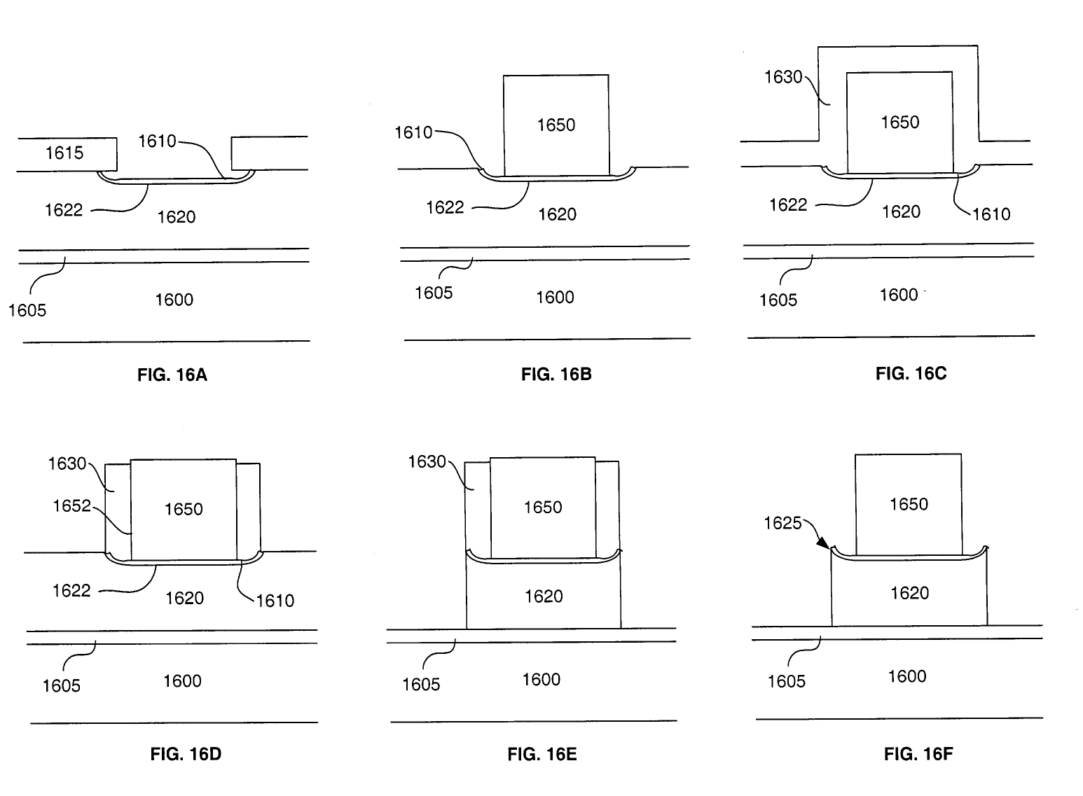

The method of the present invention can also be used to form polysilicon floating gates with injection tips for flash memory devices, as shown in FIGS. 16A to 16F. FIG. 16A shows a dip 1622 formed in a polysilicon layer 1620, which is in turn formed over an oxide layer 1605 on a substrate 1600. A thin oxide layer 1610 is formed to cover the dip 1622. Illustratively, the dip can be formed by masking the polysilicon layer with a silicon nitride mask 1615 and then etching the polysilicon layer 1620 using a conventional etching process that isotropically etches polysilicon. The thin oxide layer 1610 can be formed using conventional thin oxide layer formation techniques while the silicon nitride mask 1615 is still in place. After the nitride mask 1615 is stripped, any one of a variety of structures 1650 is formed over a middle part of the dip 1622, as shown in FIG. 16B. An edge part of the tip and portions of the thin oxide layer thereon are not under structure 1650 but extend beyond sidewalls 1652 of the structure. The structure 1650 may include microstructures typically included in flash memory devices, the details of which are not germane to the present invention. The specific techniques to form the dip 1622, the thin oxide layer 1610, and structure 1650, as shown in FIG. 16B, are also not germane to the present invention.

Conventionally, to form the polysilicon floating gate, substrate 1600 and the layers and structure formed thereon as shown in FIG. 16B are exposed to a plasma that anisotropically etches the polysilicon layer 1620. This method is not robust because the thin oxide layer 1610 not under the structure 1650 is exposed to the plasma and is subject to damage by the plasma.

The present invention uses a polymer layer to cover the part of the thin oxide layer 1610 not under the structure 1650 and to prevent it from being exposed to the plasma of the polysilicon etching process. As shown in FIG. 16C, when method 100 is used to form the polysilicon floating gate, a polymer film 1630 is deposited in step 110 to cover the structure 1650, the thin oxide 1610 and polysilicon layer 1620 not under the structure 1650. The thickness of the polymer film on sidewalls 1652 of the structure 1650 should be thick enough to extend slightly beyond edges 1623 of the dip 1622, as shown in FIG. 16C. Thereafter, in step 120 of the method 100, a first part of the polymer film is removed. As shown in FIG. 16D, the first part of the polymer film includes the part of the polymer film not covering the sidewalls 1652 of the structure 1650. In one embodiment of the present invention, an anisotropic or near anisotropic polymer etching process is used to remove the first part of the polymer film 1630. As an example, the polymer film 1630 can be etched in the DPS reactor 200 sing O₂/Cl₂ as the process gas, 4 mT gas pressure, 500 W source power, 60 W bias power, and 30/70 sccm flow rates for the O₂/Cl₂ components of the process gas, respectively. This polymer etching process often has an isotropic component that laterally etches the polymer film and can be controlled so that the thickness of the polymer film left on the sidewalls 1652 of the structure 1650 after the polymer etching process is roughly the same as the extent of the thin oxide layer 1610 beyond the sidewalls 1652 of the structure 1650, as shown in FIG. 16D.

The remaining part of the polymer film protects the thin oxide layer 1610 during the subsequent step 130, in which the polysilicon layer 1620 is etched to form the floating gate, as shown in FIG. 16E. For example, step 130 may be performed in the DPS reactor using Cl₂/HBr as the process gas where the pressure is 50 mT, the source power is 800 W, the bias power is 20 W, and the Cl₂/HBr flow rates are 20/80 sccm, respectively. This polysilicon etching process is selective to the polymer film and to an oxide material, which is often included in the structure 1650. After the polysilicon etching step 130, the polymer film 1630 is stripped in step 140, as shown in FIG. 16F, by exposing the substrate to an O₂ plasma in a plasma etcher, such as the DPS reactor. This way, the thin oxide layer 1610 covering the polysilicon floating gate with the injection tips 1625 is not affected by the polysilicon etching process.

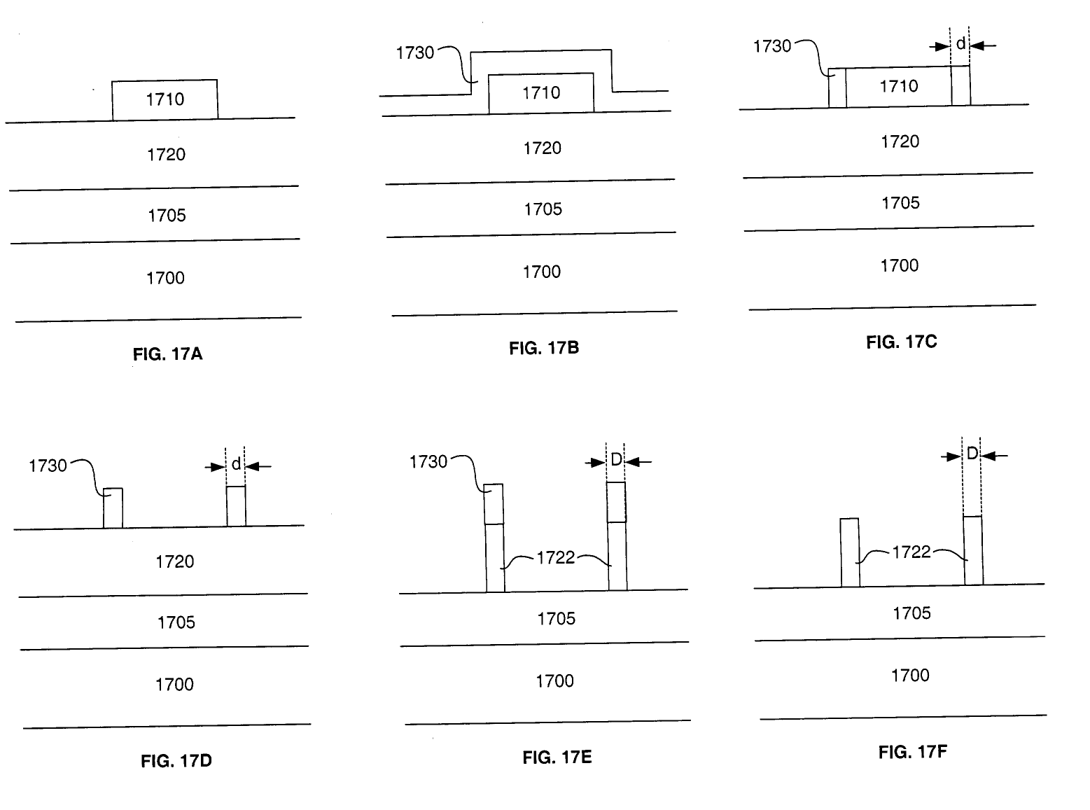

The method of the present invention can also be used to form ultra narrow lines of a material on a substrate, as shown in FIGS. 17A to 17F. FIG. 17A shows a patterned sacrificial layer 1710 formed over a layer of a first material 1720, which is in turn formed over a layer of a second material 1705 on a substrate 1700, using conventional techniques. In one embodiment of the present invention, the first material 1720 is silicon or polysilicon, the second material 1705 is silicon dioxide, and the sacrificial layer 1710 is silicon dioxide. In another embodiment of the present invention, the first material 1720 is silicon dioxide, the second material 1705 is silicon or polysilicon, and the sacrificial layer 1710 is silicon, polysilicon or a combination of silicon and germanium. The thickness of the sacrificial layer 1710, the layer of the first material 1720, or the layer of the second material 1705 depends on specific applications.

As shown in FIG. 17B, when method 100 is used to form ultra narrow lines, a polymer film 1730 is deposited in step 110 to cover the patterned sacrificial layer 1710 and the layer of the first material 1720 not under the patterned sacrificial layer 1710. Thereafter, in step 120 of the method 100, a first part of the polymer film is removed. Specifically, the part of the polymer film not on sidewalls 1712 of the patterned sacrificial layer 1710 is removed, as shown in FIG. 17C. In one embodiment of the present invention, an anisotropic or near anisotropic polymer etching process is used to remove the first part of the polymer film 1730. As an example, the polymer film 1730 can be etched in the DPS reactor 200 using O₂/Cl₂ as the process gas, 4 mT gas pressure, 500 W source power, 60 W bias power, and 30/70 sccm flow rates for the O₂/Cl₂ components of the process gas, respectively. Step 110 and 120 can be controlled such that a desired thickness d of the polymer film on the sidewalls 1712 of the patterned sacrificial layer 1710 is left after the polymer etching process.

Afterwards, the patterned sacrificial layer 1710 is removed, as shown in FIG. 17D. When the patterned sacrificial layer 1710 is made of silicon dioxide, it can be removed with HF wet etch. When the patterned sacrificial layer 1710 is silicon, polysilicon, or a combination of silicon and germanium, it can be removed with NH₄OH wet etch.

Next, step 130 in method 100 is performed, in which the polymer film 1730 left after the removal of the patterned sacrificial layer 1720 acts as a mask in a plasma etching process that anisotropically etches the layer of the first material 1720, as shown in FIG. 17E. This way, very narrow lines of the first material can be made in a controlled manner. The width D of the lines of the first material, as shown in FIG. 17E, which may be slightly smaller or greater than the thickness d of the polymer film, can be made much smaller than those achievable using conventional photolithography masking techniques. Method 100 can also be combined with conventional photolithography to form patterns in the first material with different feature sizes. For example, before step 130, photolithography can be performed to form a photoresist mask with different feature sizes on the layer of the first material in addition to the polymer film mask 1730.

When the first material is silicon, polysilicon, or a combination of silicon and germanium, step 130 may be performed in the DPS reactor using Cl₂/HBr as the process gas where the pressure is 4 mT, the source power is 500 W, the bias power is 80 W, and the Cl₂/HBr flow rates are 60/120 sccm, respectively. When the first material is silicon dioxide, it can be etched in step 130 in the DPS chamber using CF₄/CHF₃/Ar as the process gas, where the gas pressure is about 10 mT, the source power is about 500 W, the bias power is 100 W, and the flow rates for the CF₄/CHF₃/Ar gaseous components are about 15/25/110 sccm, respectively. After step 130, the polymer film 1730 is stripped in step 140, by exposing the substrate to an O₂ plasma in a plasma etcher, such as the DPS reactor. This way, ultra narrow lines 1722 of the first material are formed, as shown in FIG. 17F.

When the first material is silicon, the ultra narrow lines 1722 can be silicon fins for double-gate MOSFETs or FinFETs, such as those described by Yang-Kyu Choi et al., in “A Spacer Patterning Technology for Nanoscale CMOS,” IEEE Transactions on Electron Devices, Vol. 49, No. 3, March 2002. When the first material is polysilicon, the ultra narrow lines 1722 can be ultra short polysilicon gates for MOSFET devices. When the first material is silicon dioxide, the ultra narrow lines 1722 can be used as a hardmask for etching the layer of the second material. In this case, the layer of the first material can be much thinner than the layer of the second material.

Step 120 in the method 100 involves the formation of a polymer layer using a plasma process. Plasma formed polymers have been used in various technology fields. Because of the excellent abrasion resistance exhibited by many of these films, popular uses include wear-resistant protective coatings, corrosion-resistant and abrasion-resistant optical coatings, biomedical coatings, etc. Plasma polymers have also been used as low-surface-energy coatings to provide hydrophobic and non-sticking properties. Polymer films prepared using plasma enhanced chemical vapor deposition (PECVD) have been used for the fabrication of transparent dielectric optical films and coatings. Furthermore, plasma-formed fluorinated carbon films are potential choices for low-k inter-metal dielectrics in ultra-large-scale integrated circuit (ULSI) devices. As a result, various plasma processes have been developed to form polymer layers on substrates and many of the conventional polymer-forming plasma processes can be used to form the polymer layer in step 110. For example, the plasma process described by Wagner and Koidl in “Process Monitoring of α-C:H Plasma Deposition,” supra, or the plasma process decribed by X. Chen, et al. in “Amorphous Hydrogenated Carbon film Formation from Benzene by Electron Cyclotron Resonance Chemical Vapor Deposition,” supra, can be used to perform the polymer deposition step 110 in method 100.

In one embodiment of the present invention, step 110 as well as steps 120 to 140 in method 100 are performed consecutively in the same plasma etcher, such as the DPS reactor 200, so that there is less need to transfer the substrate between different plasma chambers in order to carry out the method 100. This results in shortened production time and reduced likelihood of defect formation caused by particles encountered during the substrate transfers.

FIG. 2B is a flow chart illustrating a process sequence (sequence) 270 for forming the polymer film on a substrate, using the reactor 200, according to one embodiment of the present invention. The sequence 270 includes step 272, in which the substrate temperature is set and further maintained at a predetermined value by the temperature control mechanism associated with the reactor 200.

The sequence 270 further includes step 274, in which gaseous components are introduced into the chamber 210 through gas entry ports 226 to form the process gas in the chamber 210. The volumetric flow rate (flow rate) of each gaseous component may be individually controlled by a gas panel (not shown) coupled to the chamber 210. Alternatively, the process gas may be pre-mixed before introduction into the chamber 210 and the gas panel controls the total process gas flow rate. The sequence 270 further includes step 276, in which the pressure of the process gas in the process chamber 210 is adjusted by regulating a position of the throttle valve 227.

The sequence 270 further includes step 278, in which the first power generator 218 is turned on to ignite the process gas in processing chamber 210 to form the plasma. Thereafter or about simultaneously with igniting the plasma, at step 279 in the process sequence 270, the second power generator 222 may be adjusted to electrically bias the wafer support pedestal with respect to the plasma.

When the polymer film has reached a desired thickness, the plasma is turned off at step 280, by turning off both the first and the second power generators.

The foregoing steps of the sequence 270 need not be performed sequentially, e.g., some or all of the steps may be performed simultaneously or in different order. In one embodiment of the present invention, sequence 270 is executed by the controller 260 as shown in FIG. 2A according to program instructions stored in memory 262. Alternatively, some or all of the steps in the sequence 270 may be performed in hardware such as an application-specific integrated circuit (ASIC) or other type of hardware implementation, or a combination of software or hardware.

In one embodiment of the present invention, the process gas used to form the polymer film includes a fluorocarbon or hydrofluorocarbon gas and a hydrogen-containing gas. Suitable fluorocarbon or hydrofluorocarbon gases include CF₄, C₂F₄, C₂F₆, C₃F₆, C₃F₈, C₄F₈, C₄F₁₀, CHF₃, CH₂F₂, C₂HF₄, C₂H₂F₄, etc., among which CF₄ or CHF₃ is more often used. Suitable hydrogen-containing gases include HBr and HCl, of which HBr is more often used. One possible mechanism by which the polymer film is formed using the process gas of the present invention is the fluorine-depletion mechanism, as illustrated by the following dissociation and recombination reactions

CₓH_{y}F_{z} [symbol] CₓH_{y}F_{w}+F,

HBr [symbol] H+Br,

H+F [symbol] HF,

and

nCₓH_{y}F_{w} [symbol] polymer film,

where x, z, and w are positive integers and z>w, and y is either zero or a positive integer. In the above equations, CₓH_{y}F_{z} represents the fluorocarbon or hydrofluorocarbon gas molecules that dissociate in the plasma into fluorine radicals (F) and fluorine-depleted fluorocarbon or hydrofluorocarbon radicals (CₓH_{y}F_{w}). Meanwhile, HBr represents the HBr molecules that dissociate into hydrogen radicals (H) and bromine radicals (Br). Due to the strong H—F bond, the F radicals dissociated from the fluorocarbon or hydrofluorocarbon molecules are likely to react with the H radicals dissociated from the HBr gas molecules to form HF gas molecules. The fluorine depleted fluorocarbon or hydrofluorocarbon species are then left to react with each other to form the polymer film on the substrate.

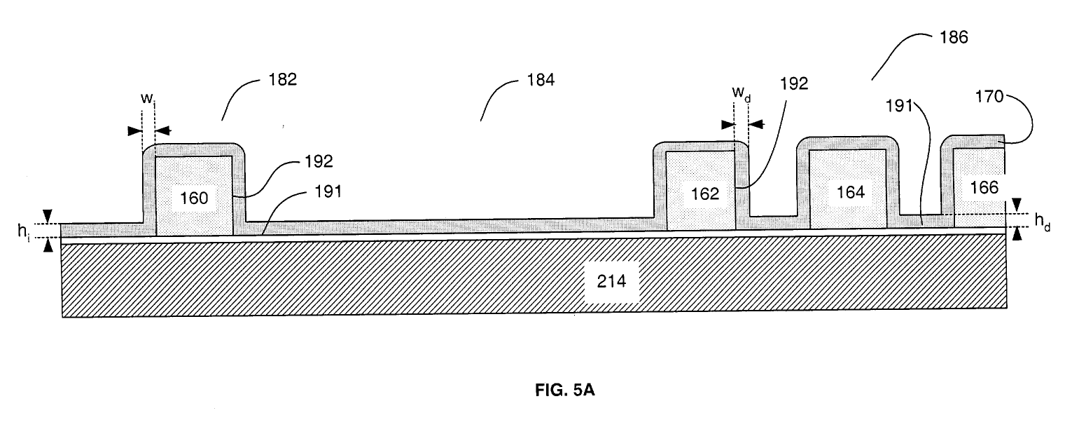

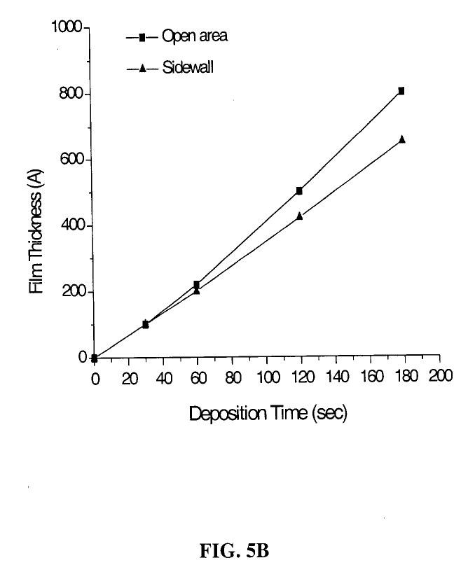

In one embodiment of the present invention, the polymer film in step 110 is formed in the DPS plasma reactor using CHF₃/HBr as the process gas where the gas pressure is about 30 mT, the source power is about 600 W, the bias power is about 120 W, the total process gas flow rate is about 100 sccm, and the CHF₃ flow rate is about 50 sccm, or about 50% of the total flow rate. The deposition process is performed until a desired thickness of the polymer film is reached in open areas of the substrate. The deposition time may be predetermined based on pre-characterized deposition rate data, such as that shown in FIG. 5, as described below, or the deposition process may be terminated by an in-situ polymer film thickness measurement technique that signals controller 260 to turn off the plasma when a desired polymer film thickness is measured in an open area on the substrate. In one embodiment of the present invention, the deposition time is about 120 seconds.

By varying process parameters such as the process gas composition, the flow rate at which the process gas is introduced into the plasma chamber, the gas pressure in the plasma chamber, the source power, and the bias power, polymer films with different properties can be formed, as described in more detail below. In one embodiment of the present invention, the gas pressure is varied in the range of about 6-50 mT, the source power in the range of about 300-1000 W, the bias power in the range of about 0-150 W, and the percentage of the fluorocarbon gas in the process gas in the range of about 20-80%. Examples of the process parameters used to form the polymer films in one embodiment of the present invention are listed in Table I.

TABLE I

| | Example 1 | Example 2 | Example 3 | Example 4 |
|---|---|---|---|---|
| Process Gas | 50% CHF₃ | 50% CF₄ | 50% CHF₃ | 50% CHF₃ |
| Composition | 50% HBr | 50% HBr | 50% HBr | 50% HBr |
| Total Gas Flow | 100 sccm | 100 sccm | 100 sccm | 100 sccm |
| Rate | | | | |
| Pressure (mT) | 6 | 6 | 30 | 30 |
| Source Power | 600 | 600 | 600 | 600 |
| (W) | | | | |
| Bias Power (W) | 0 | 0 | 0 | 80 |
| Substrate | 50° C. | 50° C. | 50° C. | 50° C. |

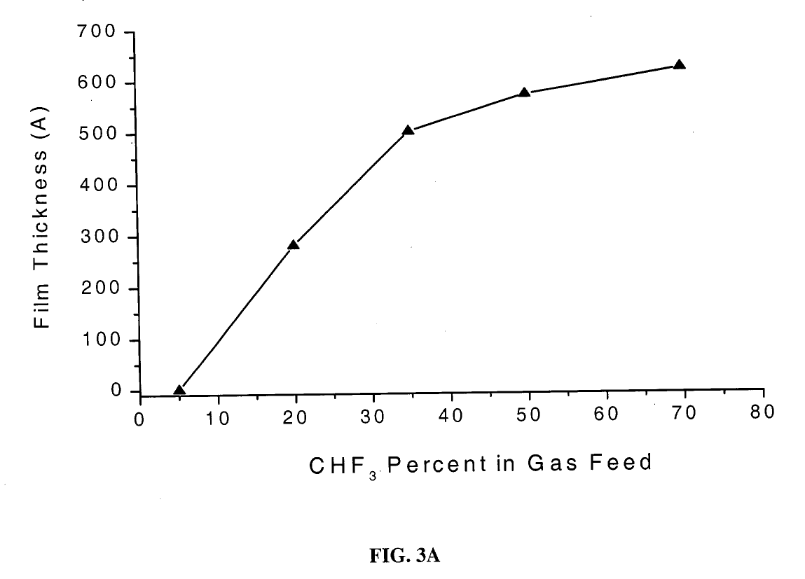

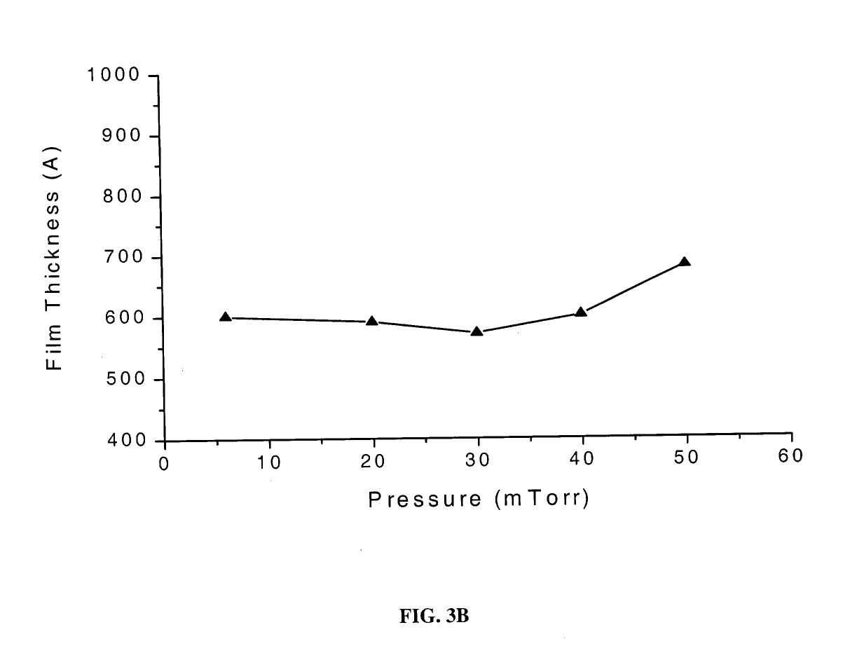

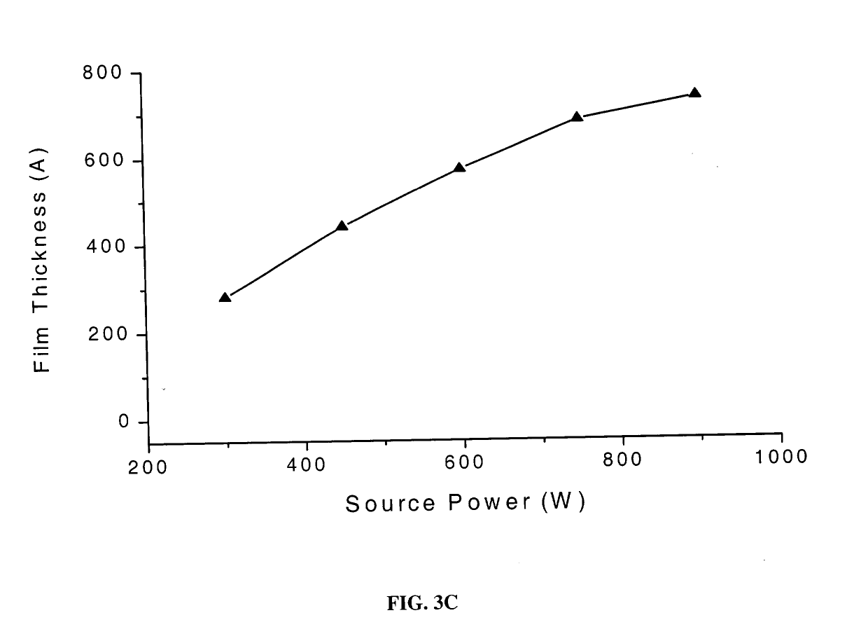

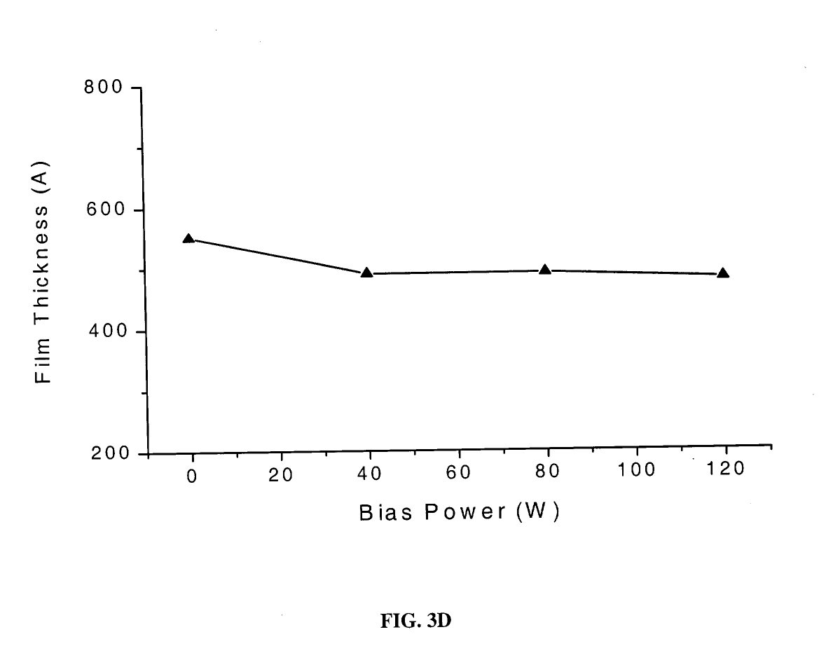

To determine the effect of process parameters on the thickness of the polymer film formed in a fixed time period, blank silicon wafers were exposed to polymer film formation processes having different process parameters for a fixed time period, such as 3 minutes, and measurements on the film thickness were the taken. The effect of the process parameters on the film thickness is shown in FIGS. 3A-3D. Specifically, FIG. 3A shows the film thickness data taken from films formed using the process parameters in Example 1 in Table I, except that the percentage of CHF₃ is varied. As shown in FIG. 3A, the film thickness increases as the percentage of CHF₃ increases.

FIG. 3B shows the film thickness data taken from films formed using the process parameters in Example 1 in Table I except that the pressure is varied. As shown in FIG. 3B, the film thickness does not change much when pressure is varied from about 6 mT to about 30 mT, but further increase in the pressure beyond 30 mT results in increased film thickness. FIG. 3C shows film thickness data taken from films formed using the process parameters in Example 3 in Table I except that the source power is varied. As shown in FIG. 3C, the film thickness increases as the source power is increased until the source power reaches about 900 W. FIG. 3D shows film thickness data taken from films formed using the process parameters in Example 3 in Table I except that the bias power is varied. As shown in FIG. 3D, higher bias power results in slightly thinner C-films.

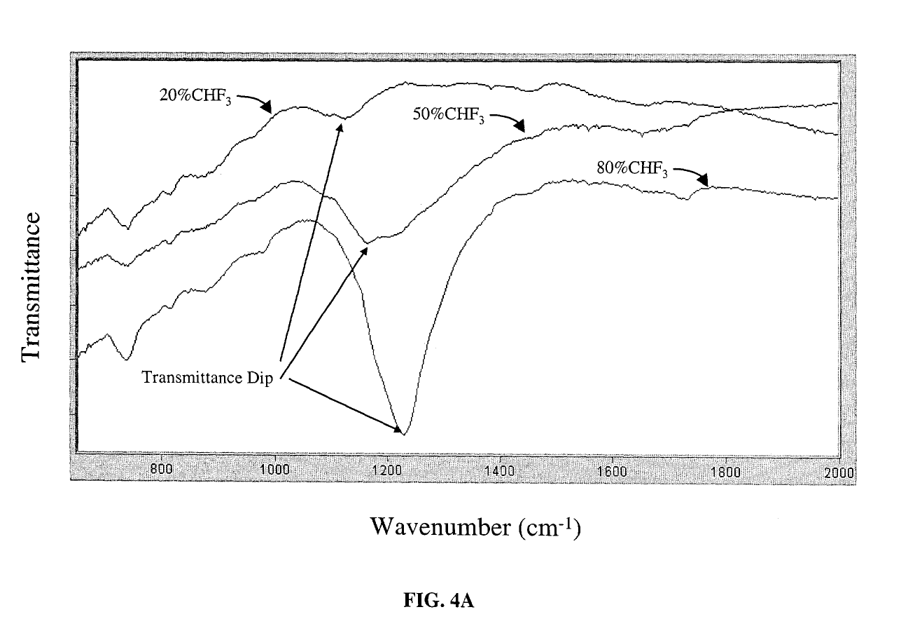

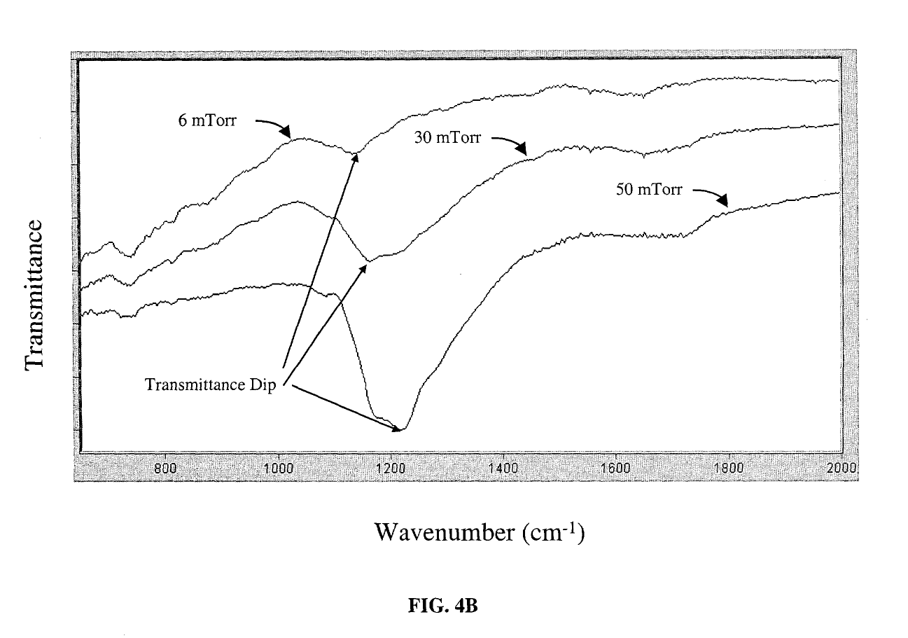

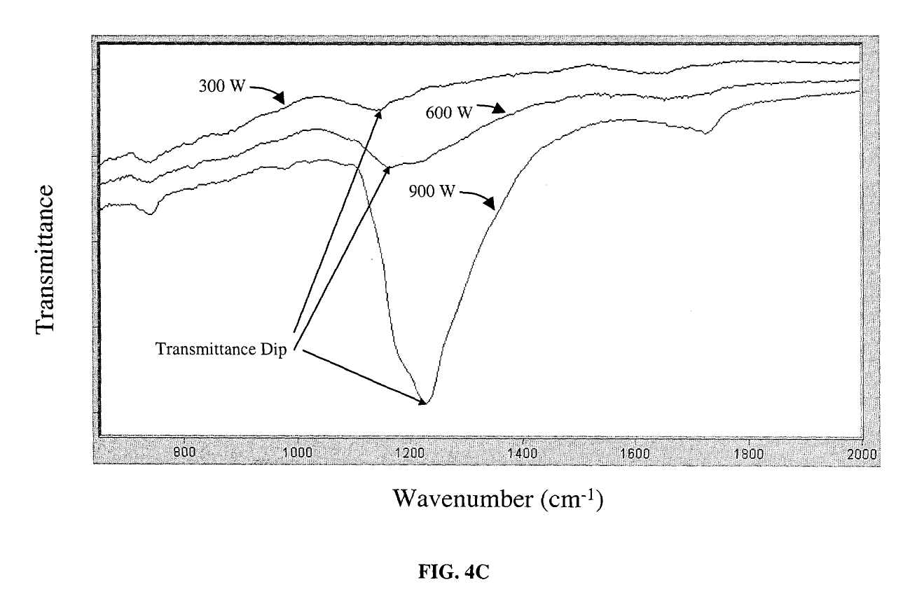

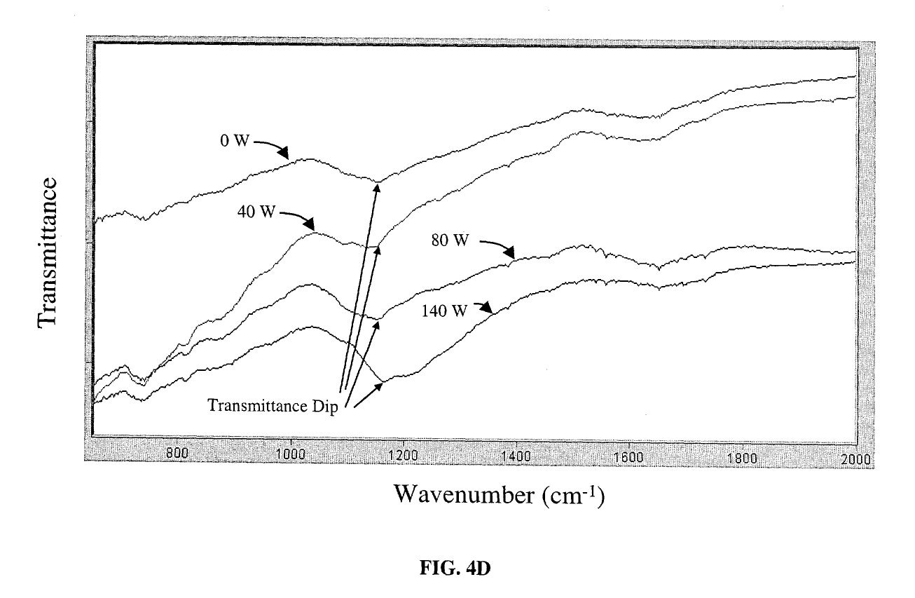

Polymer film of about 500 Å thickness formed on blank silicon substrates using different process parameters were examined using a Fourier Transform Infrared (FTIR) spectrometer. The FTIR spectrometer recorded interactions of infrared radiation with the polymer film and measured the transmittance against frequency. This way, functional groups and highly polar bonds in the polymer film can be determined through FTIR spectra taken from the polymer film. FIG. 4A includes FTIR spectra taken from polymer film formed using the process parameters in Example 3 in Table I except that the percentage of CHF₃ is varied. As shown in FIG. 4A, each polymer film FTIR spectrum shows a transmittance dip at about 1200 ^{cm-1} wavelength, indicating the presence of C—F stretch bonds in the polymer film. As shown in FIG. 4A, the intensity of the C—F stretch dip increases as the percentage of CHF₃ increases, indicating more C—F bonds and higher F concentration. FIG. 4B includes FTIR spectra taken from C-films formed using the process parameters in Example 3 in Table I except that the process gas pressure is varied. As shown in FIG. 4B, the intensity of the C—F stretch dip increases as the pressure increases, indicating more C—F bonds and higher F concentration with higher pressure. FIG. 4C includes FTIR spectra taken from C-films formed using the process parameters in Example 3 in Table I except that the source power is varied. As shown in FIG. 4C, the intensity of the C—F stretch dip increases as the source power increases, indicating more C—F bonds and higher F concentration with higher source power. FIG. 4D includes FTIR spectra taken from C-films formed using the process parameters in Example 3 in Table I except that the bias power is varied. As shown in FIG. 4D, the intensity of the C—F stretch dip increases only slightly as the bias power increases, indicating small influence of the bias power on the number of C—F bonds and F concentration in the C-films.

To determine the linearity of a polymer film deposition rate, i.e., the rate at which the thickness of the polymer film increases with time during the polymer film deposition process, silicon substrates with polysilicon lines formed thereon were exposed for different periods of time to the plasma process having the process parameters in Example 3 in Table I. FIG. 5A illustrates a polymer film 170 formed over an isolated polysilicon line 160, an open area 184, and a series of line and space patterns 186 on a substrate 214. The substrate 214 can be a semiconductor substrate, such as a silicon wafer, with or without one or more layers of materials formed thereon. The thickness of the polymer film were then measured at the sidewalls of isolated polysilicon lines and on bottom surfaces 191 in an open area (such as the area 184), as shown in FIG. 5A. The results are shown in FIG. 5B. As shown in FIG. 5B, the deposition rate stays roughly linear with time. The linearity helps to determine the length of time for a polymer film deposition process based on the thickness of the polymer film desired.

To determine the effect of process parameters on the conformality and microloading of polymer films formed on patterned substrates, silicon substrates with polysilicon lines formed thereon were exposed to plasma processes having different process parameters for a fixed time period, such as 2 minutes. FIG. 5A illustrates a polymer film 170 formed in the DPS reactor 200 over a substrate 214 having polysilicon lines 160, 162, 164, and 166 previously formed thereon. The thickness of the polymer films are then measured at the bottom surface 191 and sidewalls 192 of the polysilicon lines in areas where the polysilicon lines are densely packed (such as the area 186) and in areas where the polysilicon lines are far apart from each other (such as the area 182 near the isolated line 160), as shown in FIG. 5A.

The conformality of the polymer film in the isolated areas is defined as

$${C}_{i} = \frac{{w}_{i}}{{h}_{i}} ,$$

and the conformality of the polymer film in the dense areas is defined as

$${C}_{d} = \frac{{w}_{d}}{{h}_{d}} ,$$

where, as shown in FIG. 5A, wᵢ and hᵢ are the film thickness on the sidewall of an isolated line and the film thickness on a bottom surface near the isolated line, respectively; and w_{d} and h_{d} are the film thickness on the sidewall of a line among densely packed line and space patterns and the film thickness on a bottom surface in the densely packed line and space patterns, respectively.

The microloading for the film thickness on the sidewalls can be defined as

$${M}_{w} = \frac{\vert {w}_{i} - {w}_{d} \vert}{{w}_{i}} ,$$

Similarly, the microloading for the film thickness on the bottom surface can be defined as:

$${M}_{h} = \frac{\vert {h}_{i} - {h}_{d} \vert}{{h}_{i}} ,$$

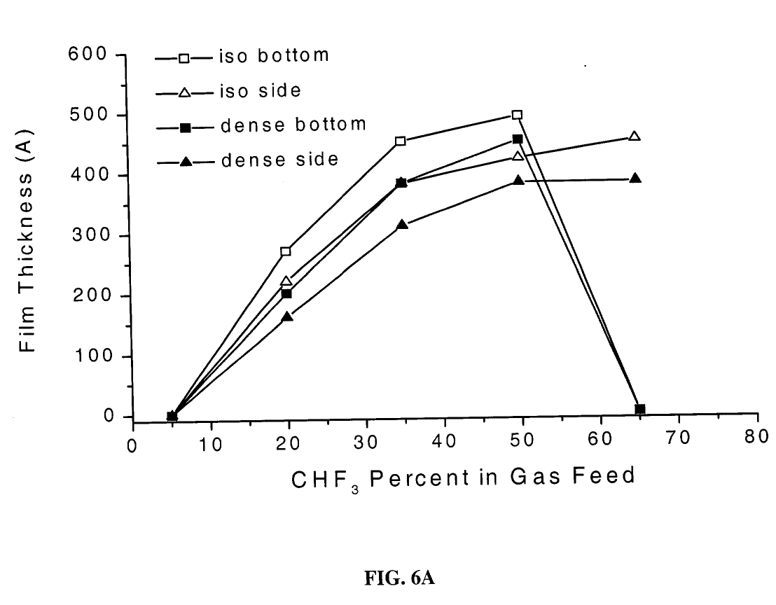

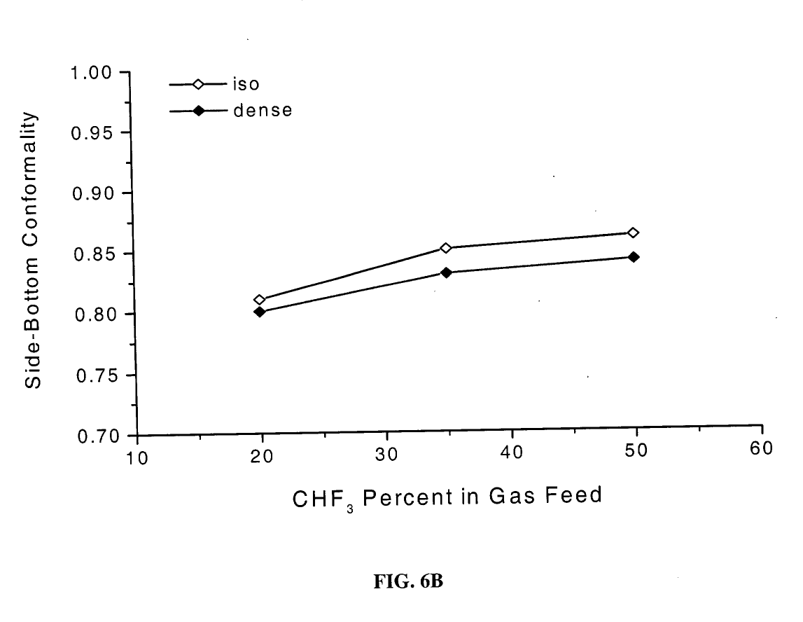

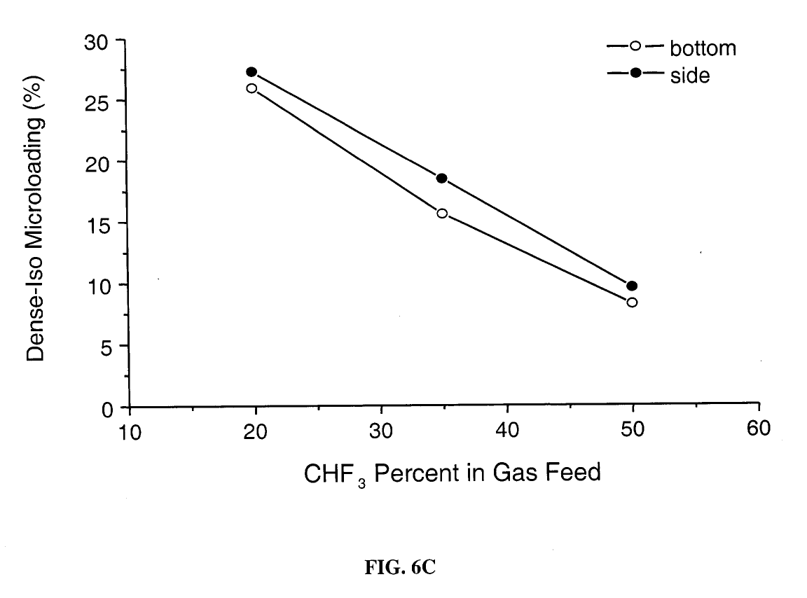

FIG. 6A is a chart illustrating the results of the film thickness measurements taken from polymer film formed using the process parameters in Example 4 in Table I except that the CHF₃ percentage is varied. The conformality and microloading are then calculated from the film thickness data and the results are shown in FIGS. 6B and 6C, respectively. As shown in these figures, both the conformality and microloading of the polymer film improve with increased percentage of CHF₃ flow rate in the total process gas flow rate, up to a CHF₃ percentage of 50%. A conformality higher than about 0.8 can be reached when the percentage of CHF₃ flow rate is higher than about 20%.

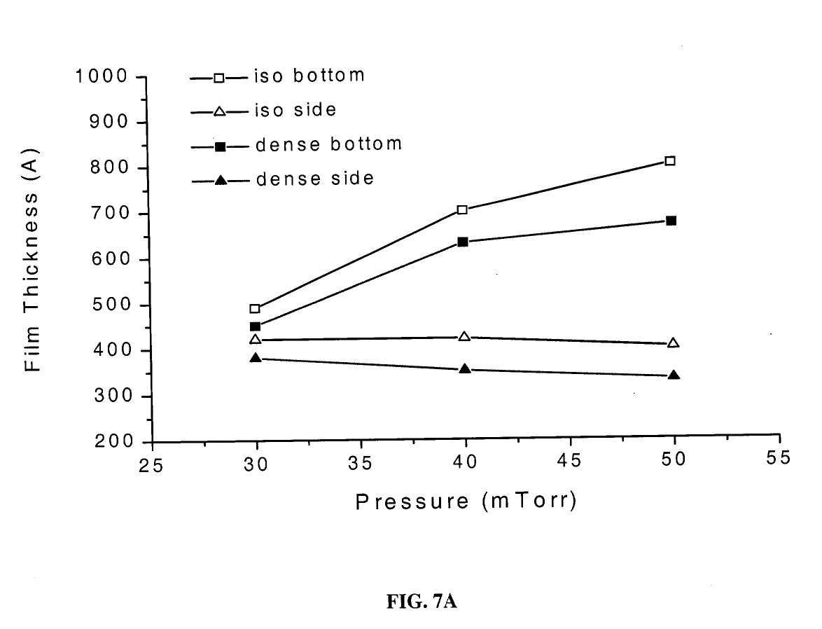

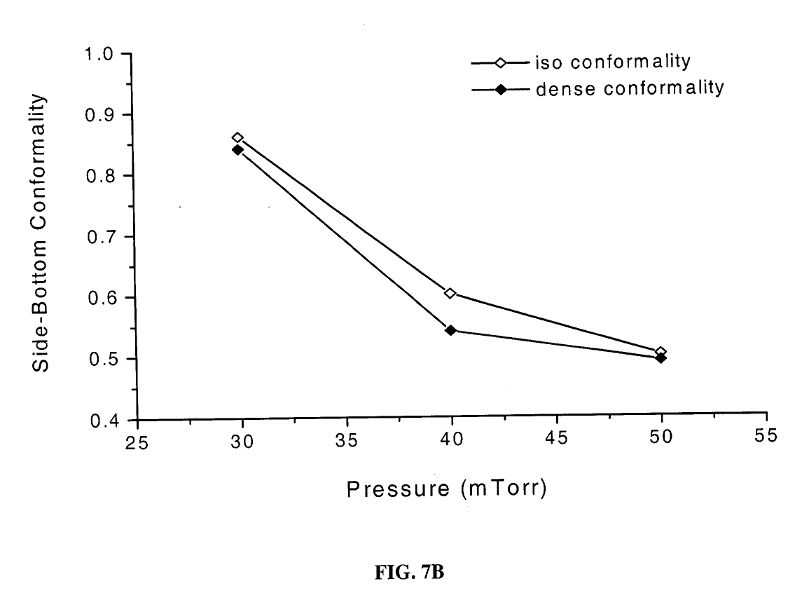

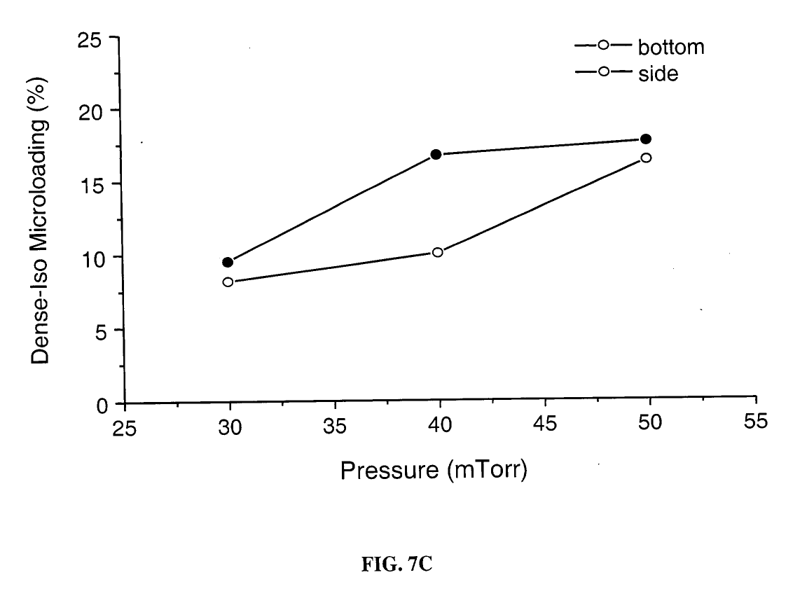

FIG. 7A is a chart illustrating the results of the film thickness measurements taken from polymer film formed using the process parameters in Example 4 in Table I except that the process gas pressure is varied in the range of 30-50 mT. The conformality and microloading are then calculated from the film thickness data and the results are shown in FIGS. 7B and 7C, respectively. As shown in these figures, the conformality improves sharply with decreasing pressure, and a conformality higher than about 0.8 can be reached when the pressure is lower than about 30 mT. The microloading also improves slightly when the pressure is lowered. This indicates an advantage of using high density plasmas to form polymer film on patterned substrates, as high density plasmas can be maintained in a lower pressure range than low-density plasmas, such as those created using PECVD chambers.

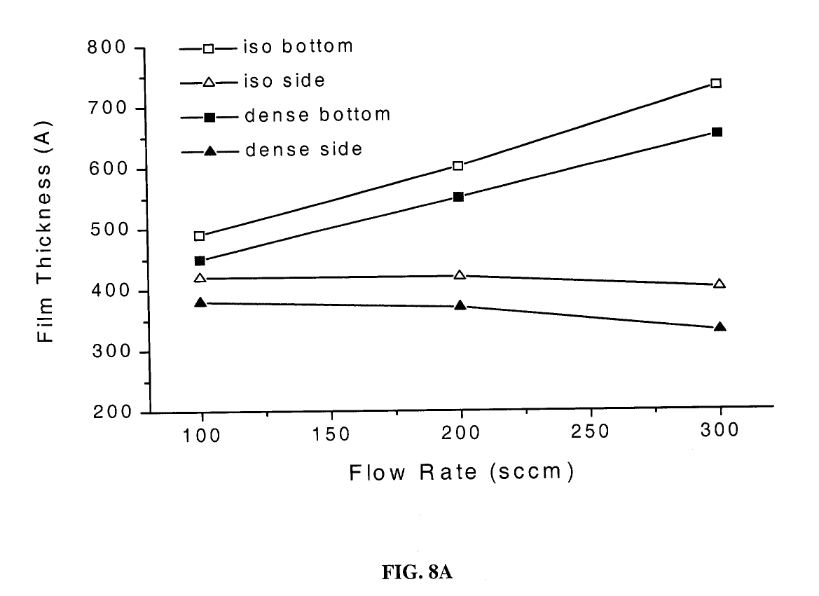

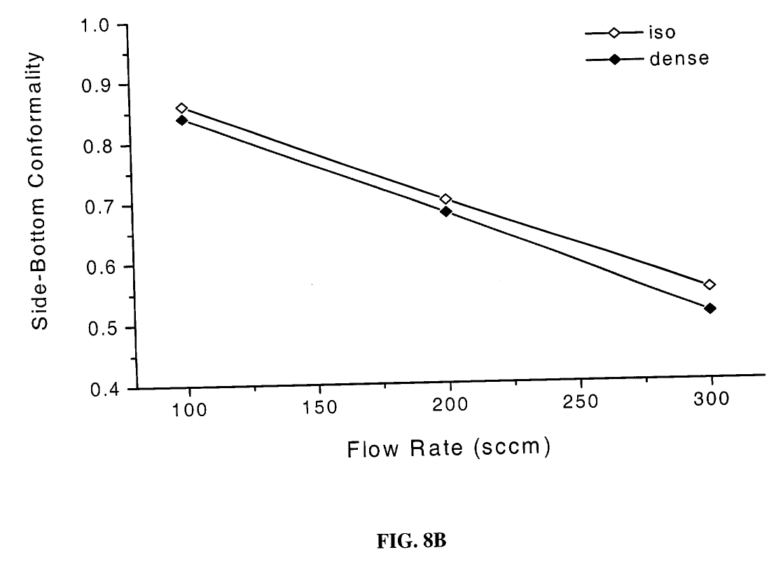

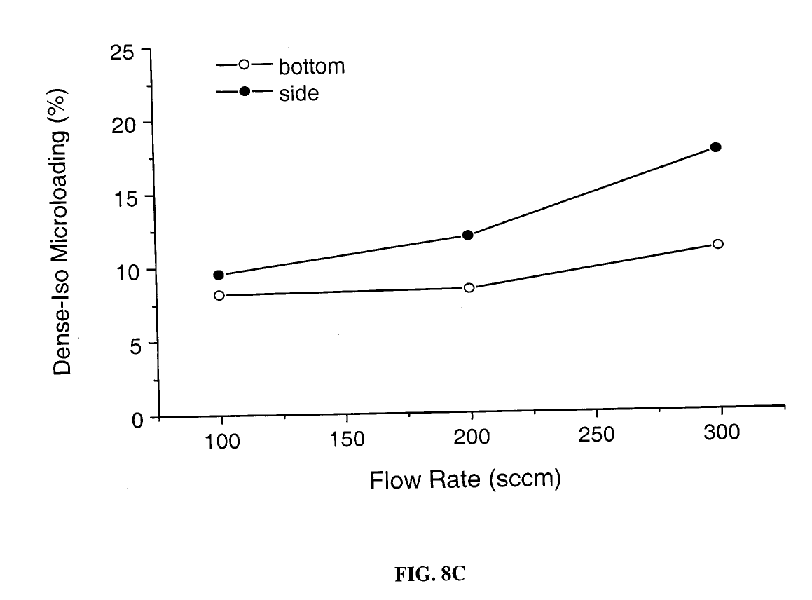

FIG. 8A is a chart illustrating the results of the film thickness measurements taken from polymer film formed using the process parameters in Example 4 in Table I except that a total gas flow rate is varied in the range of 100-300 sccm. The total gas flow rate is the sum of the flow rate of each gaseous component in the process gas. The conformality and microloading are calculated from the film thickness data and the results are shown in FIGS. 8B and 8C, respectively. As shown in these figures, the conformality declines sharply with increasing total gas flow rate, and the microloading also gets worse when the total gas flow rate increases.

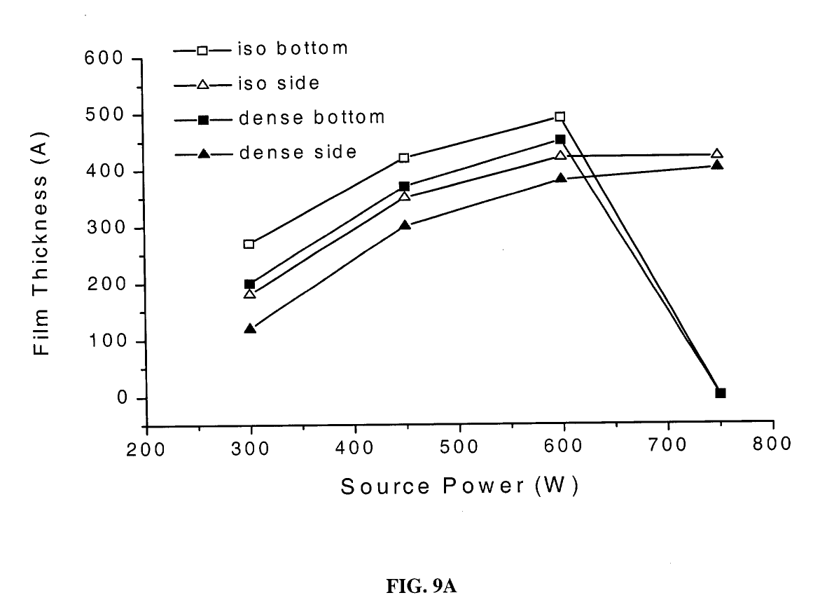

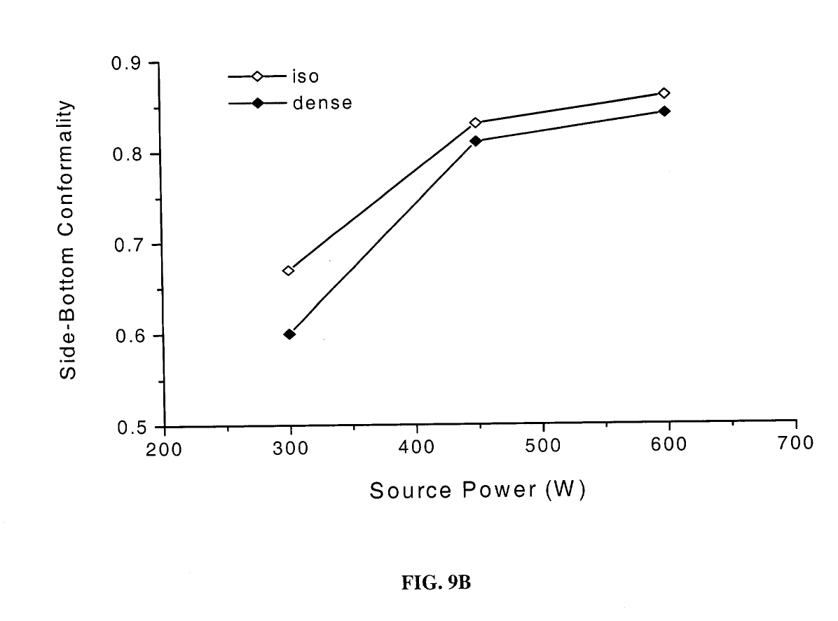

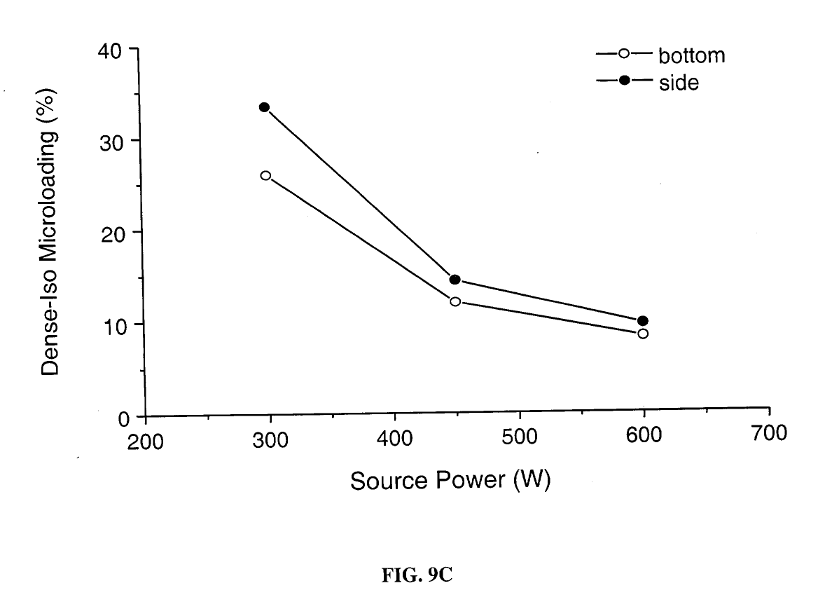

FIG. 9A is a chart illustrating the results of the film thickness measurements taken from polymer film formed using the process parameters in Example 4 in Table I except that the source power is varied in the range of 300-750 W. The film thickness at the bottom surface increases with source power until it reaches a maximum, and then decreases sharply as the source power is further increased. The decrease in film thickness is due to the fact that a sputtering process becomes dominant at high source power. The film thickness on the sidewall, on the other hand, keeps increasing with the increasing source power because the sidewalls are less subjected to the ion bombardment. The conformality and microloading are calculated from the film thickness data and the results are shown in FIGS. 9B and 9C, respectively. As shown in these figures, both the conformality and microloading improve sharply with increasing source power. When the source power is higher than about 430 W, a conformality higher than about 0.8 can be reached.

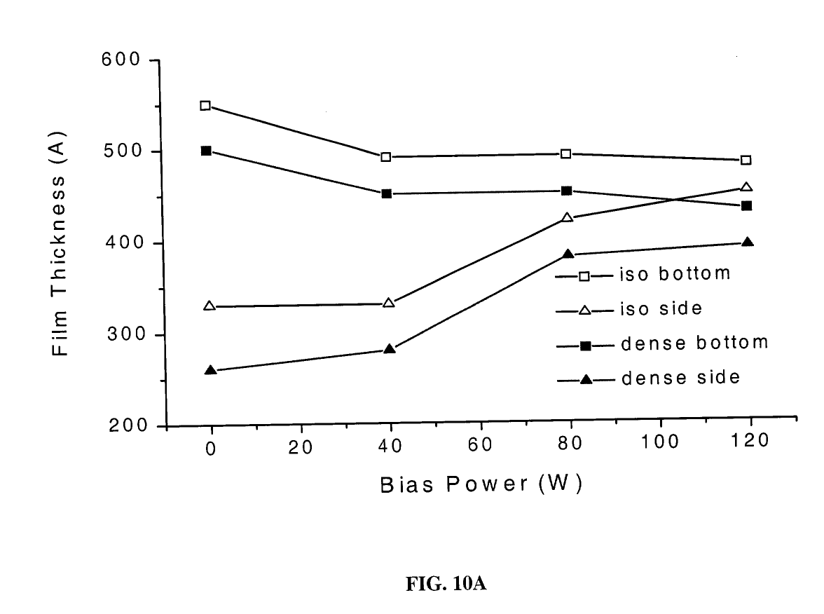

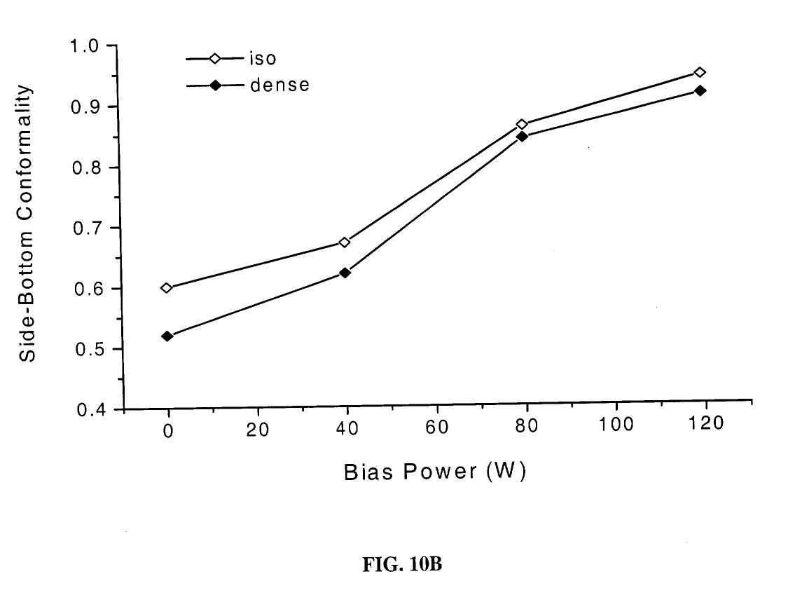

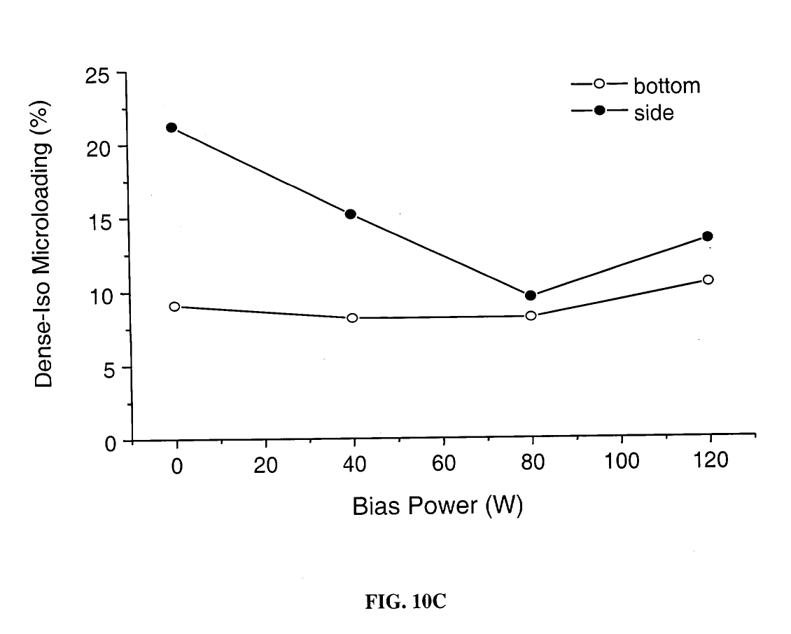

FIG. 10A is a chart illustrating the results of the film thickness measurements taken from polymer film formed using the process parameters in Example 4 in Table I except that the bias power is varied in the range of 0-110 W. The conformality and microloading are then calculated from the film thickness data and the results are shown in FIGS. 10B and 10C, respectively. As shown in these figures, as the bias power increases, the conformality improves sharply, with some sacrifice in microloading, especially in microloading of the film thickness at the bottom surfaces of the polymer film. Thus a compromise between the conformality and microloading of the polymer film needs to be considered when setting the bias power.

In order to act as protective layers or mask layers, the resistance of the polymer film to the plasma processes for etching other layers of materials in method 100 is important. To determine the effect of process parameter variations on the resistance of the polymer films formed therewith to silicon or polysilicon etching processes, polymer films are formed on blank silicon substrates using polymer film deposition processes with different process parameters. The thickness of each polymer film is measured. These polymer films are then exposed to silicon or polysilicon etching processes performed in the DPS reactor using Cl₂/HBr as the process gas where the pressure is at 4 mT, the source power at 400 W, the bias power is at 40 W, and the substrate temperature is controlled around 50° C. Each polymer film is etched until an endpoint detector associated with the DPS reactor indicates that the polymer films have been removed from the substrates. The time to remove each polymer film is then recorded, and an etch rate of the polymer film is calculated from the thickness of polymer film and the time taken to remove the polymer film using the Cl₂/HBr plasma. High etch rate of the polymer film indicates lower etch resistance.

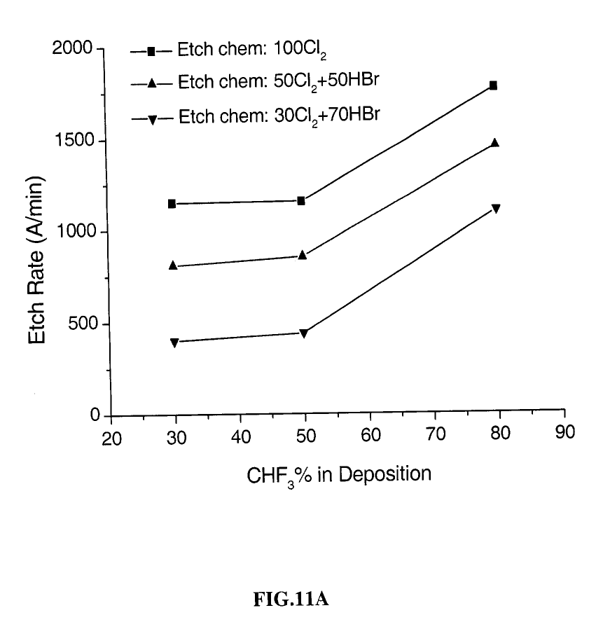

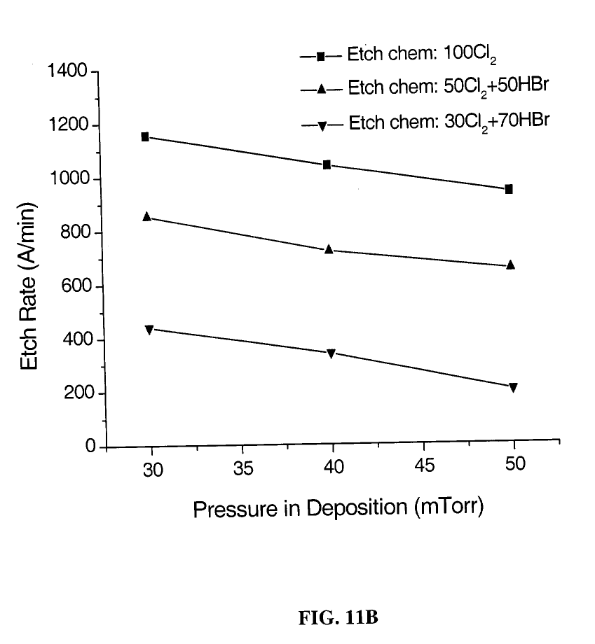

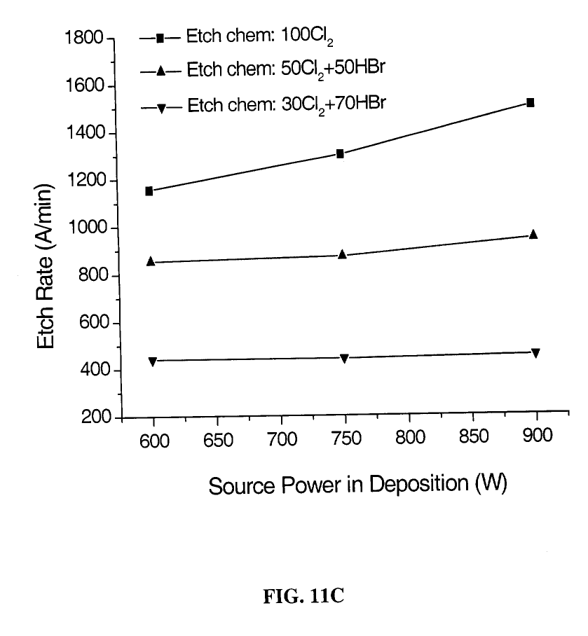

FIG. 11A includes etch rate data taken from polymer films formed using the process parameters in Example 3 in Table I except that the CHF₃ percentage is varied. The polymer films are exposed to a Cl₂/HBr etching process with different percentage of Cl₂. As shown in FIG. 11A, a high CHF₃ percentage results in a higher etch rate and thus a lower etch resistance of the polymer film. FIG. 11B includes etch rate data taken from polymer films formed using the process parameters in Example 3 in Table I except that the pressure is varied. The polymer films are exposed to a Cl₂/HBr etching process with different percentages of Cl₂. As shown in FIG. 11B, high pressure results in a lower etch rate and thus a higher etch resistance of the polymer film. FIG. 11C includes etch rate data taken from polymer films formed using the process parameters in Example 3 in Table I except that the source power is varied. The polymer films are exposed to a Cl₂/HBr etching process with different percentage of Cl₂. As shown in FIG. 11A, a high source power results in a slightly higher etch rate and thus a lower etch resistance of the polymer film, especially when a higher Cl₂ percentage is used for the etching process. FIG. 11D includes etch rate data taken from polymer films formed using the process parameters in Example 3 in Table I except that the bias power is varied. The polymer films are exposed to a Cl₂/HBr etching process with different percentages of Cl₂. As shown in FIG. 11A, an increase in bias power from 0 to about 40 W results in a significantly lower etch rate and thus a higher etch resistance of the polymer film. Further increase of the bias power beyond 40 W seems to have little influence on the etch resistance of the polymer films formed therewith.

Because the actual process parameters, such as the source power, bias power, pressure, gas flow rates, etc., are dependent upon the size of the wafer, the specific type of resist films formed on the wafer, the volume of the chamber 202, and on other hardware configurations of the reactor 200, the invention is not limited to process parameters or the ranges recited herein.

While the present invention has been described with reference to a few specific embodiments, the description is illustrative of the invention and is not to be construed as limiting the invention. Various modifications may occur to those skilled in the art without departing from the true spirit and scope of the invention as defined by the appended claims.

What is claimed is:

1. A method of forming a structure on a substrate, comprising
depositing a polymer film over a layer of material on the substrate in a plasma of a first process gas;
removing a first part of the polymer film from a part of the layer of material in a plasma of a second process gas;
etching the layer of material in a plasma of a third process gas; and
removing a second part of the polymer film.

2. The method of claim 1 wherein the first part of polymer film includes a part of the polymer film on horizontal surfaces on the substrate.

3. The method of claim 1 wherein the structure includes spacers formed on two sides of a gate and wherein the layer of material comprises one or more spacer materials covering the gate.

4. The method of claim 3 wherein the second part of the polymer film is on sidewalls of the gate.

5. The method of clam 1 wherein the structure includes a notched gate and the layer of material comprises a partially formed gate.

6. The method of claim 5 wherein the second part of the polymer film is on sidewalls of the partially formed gate.

7. The method of claim 6 wherein etching the layer of material comprises isotropically etching a lower part of the layer of material to form notches.

8. The method of claim 1 wherein the structure includes one or more silicon pillars and the layer of material is a partially etched layer of silicon.

9. The method of claim 8 wherein depositing the layer of polymer film, removing the first part of the polymer film, and etching the layer of material are repeatedly performed before removing the second part of the polymer film.

10. The method of claim 1 wherein the structure includes polysilicon floating gate with injection tips and the layer of material is polysilicon.

11. The method of claim 10 wherein the second part of the polymer film is above a thin oxide layer formed on the layer of material.

12. The method of claim 1 wherein the structure includes narrow lines formed in the layer of material and the polymer film is formed to cover a patterned sacrificial layer over the layer of material.

13. The method of claim 12 wherein the second part of the polymer film is on sidewalls of the patterned sacrificial layer.

14. The method of claim 12, further comprising removing the patterned sacrificial layer before etching the first part of the layer of material.

15. The method of claim 1 wherein depositing the layer of polymer film, removing the first part of the polymer film, etching the first part of the layer of material, and removing the second part of the polymer film are carried out in a single plasma chamber.

16. The method of claim 15 wherein the plasma chamber is a plasma etch chamber.

17. The method of claim 16 wherein the plasma chamber is a silicon or polysilicon etch chamber.

18. The method of claim 1 wherein depositing the layer of polymer film comprises:
introducing into a plasma chamber in which the substrate is situated a process gas comprising a fluorocarbon or hydrofluorocarbon gas and a hydrogen-containing inorganic gas selected from the group consisting of HBr or HCl; and
maintaining a plasma of the process gas in the plasma chamber for a period of time determined by a desired thickness of the polymer film.

19. The method of claim 18 wherein the fluorocarbon or hydrofluorocarbon gas is selected from the group consisting of CF₄, C₂F₄, C₂F₆, C₃F₆, C₃F_{8,} C₄F₈, C₄F₁₀, CHF₃, CH₂F₂, C₂HF₅, and C₂H₂F₄.

20. The method of claim 18 wherein the fluorocarbon or hydrofluorocarbon gas is CHF₃ or CF₄ and the bromine-containing gas is HBr.

21. The method of claim 18 wherein maintaining the plasma of the process gas comprises applying RF power to the plasma chamber.

22. The method of claim 21 wherein RF power is applied to one or more coils over a ceiling of the plasma chamber.

23. The method of claim 18 wherein maintaining the plasma of the process gas comprises applying a bias power to the plasma chamber to electrically bias the substrate with respect to the plasma of the process gas.

24. The method of claim 18 further comprising maintaining gas pressure in the plasma chamber at a level in the range of about 6-50 mT.

25. A computer readable medium storing therein program instructions that when executed by a computer causes a plasma reactor to form a structure on a substrate, the program instructions comprising instructions for:
depositing a polymer film over a layer of material on the substrate;
removing a first part of the polymer film from a part of the layer of material;
etching the layer of material; and
removing a second part of the polymer film.

26. The computer readable medium of claim 25 wherein the instructions for depositing the layer of polymer film comprises:
instructions for introducing into a plasma chamber in which the substrate is situated a process gas comprising a fluorocarbon or hydrofluorocarbon gas and a hydrogen-containing inorganic gas selected from the group consisting of HBr or HCl; and
instructions for maintaining a plasma of the process gas in the plasma chamber for a period of time determined by a desired thickness of the polymer film.

27. The computer readable medium of claim 25, further comprising instructions for partially etching the layer of material before depositing the polymer film over the layer of material.
